(19) United States
(12) Patent Application Publication
(10) Pub. No.: US 2026/0267508 A1
(43) Pub. Date: Sep. 10, 2026

(54) Bilateral Adaptive Codebook Compression System for Heterogeneous Compute Interconnects

(71) Applicant: AtomBeam Technologies Inc., Moraga, CA (US)

(72) Inventors: Brian Galvin, Silverdale, WA (US); Joshua Cooper, Columbia, SC (US); Charles Yeomans, Orinda, CA (US)

(21) Appl. No.: 19/657,227

(22) Filed: Apr. 24, 2026

Related U.S. Application Data
(63) Continuation-in-part of application No. 19/207,301, filed on May 13, 2025.
(63) Continuation-in-part of application No. 18/919,459, filed on Oct. 18, 2024.
Application No. 19/207,301 is a continuation-in-part of application No. 18/520,473, filed on Nov. 27, 2023, now Pat. No. 12,373,101.
Application No. 18/919,459 is a continuation-in-part of application No. 18/480,497, filed on Oct. 3, 2023, now Pat. No. 12,189,581.
Application No. 18/520,473 is a continuation of application No. 18/295,238, filed on Apr. 3, 2023, now Pat. No. 11,928,335.
Application No. 18/295,238 is a continuation of application No. 17/974,230, filed on Oct. 26, 2022, now Pat. No. 11,687,241.
Application No. 17/974,230 is a continuation-in-part of application No. 17/884,470, filed on Aug. 9, 2022, now abandoned.
Application No. 18/480,497 is a continuation of application No. 17/234,007, filed on Apr. 19, 2021, now Pat. No. 11,782,879.
Application No. 17/234,007 is a continuation-in-part of application No. 17/180,439, filed on Feb. 19, 2021, now Pat. No. 11,366,790.
Application No. 17/180,439 is a continuation-in-part of application No. 16/923,039, filed on Jul. 7, 2020, now Pat. No. 11,232,076.
(60) Provisional application No. 64/000,507, filed on Mar. 9, 2026.
(60) Provisional application No. 63/232,050, filed on Aug. 11, 2021.
(60) Provisional application No. 63/140,111, filed on Jan. 21, 2021.
(60) Provisional application No. 63/027,166, filed on May 19, 2020.

(51) Int. Cl. G06F 3/06; H03M 7/30

(52) U.S. Cl. CPC G06F 3/0608; G06F 3/0623; G06F 3/0659; G06F 3/067; H03M 7/6005; H03M 7/6011

(57) ABSTRACT

A computing system implements a bilateral compression pair between a CPU and a GPU across a PCIe, NVLink, or equivalent interconnect. The system maintains two independently trained directional codebooks, one for each traffic direction, each generated from a dedicated occurrence counter array that accumulates symbol pattern statistics for that direction without any shared training state. An encoder at each endpoint encodes outgoing protocol data units by substituting multi-byte symbol patterns with variable-length codewords assigned by the active directional codebook, embedding a codebook version number in each encoded frame header to enable correct decoding independent of concurrent version transitions. A compaction factor estimator evaluates the compression performance achievable at each of a plurality of candidate source block lengths without generating any codebook, selecting the optimal length continuously. A codebook lifecycle manager governs codebook generation, staged deployment, automatic rollback, ramp-up bootstrap, and power-state adaptation.

### CROSS-REFERENCE TO RELATED APPLICATIONS

Priority is claimed in the application data sheet to the following patents or patent applications, each of which is expressly incorporated herein by reference in its entirety:

64/000,507

19/207,301

18/520,473

18/295,238

17/974,230

17/884,470

63/232,050

18/919,459

18/480,497

17/234,007

17/180,439

63/140,111

16/923,039

63/027,166

### BACKGROUND OF THE INVENTION

### Field of the Art

The present invention is in the field of data compression for high-performance computing interconnects, and more particularly to adaptive bilateral codebook compression systems for heterogeneous processor interconnects in which independently trained directional codebooks are maintained for each direction of data transmission and continuously refined through live traffic observation.

### Discussion of the State of the Art

Data compression has long been applied to network and storage interfaces to reduce bandwidth consumption and improve system throughput. Conventional compression systems, however, were designed for symmetric, general-purpose communication channels and are poorly suited to the asymmetric, heterogeneous data paths that characterize modern high-performance computing environments. Several fundamental limitations of the prior art are relevant to the present disclosure.

What is needed is a compression system for heterogeneous processor interconnects that maintains independently trained directional codebooks for each direction of data transmission, estimates compression performance without generating candidate codebooks, eliminates the cold-start penalty through pre-seeded prior codebooks with progressive blended refinement, coordinates codebook version transitions between endpoints without data path interruption, and provides robust staged deployment and automatic rollback mechanisms, all within the computational and power constraints of on-chip deployment.

### SUMMARY OF THE INVENTION

Accordingly, the inventor has conceived and reduced to practice, a computing system implements a bilateral compression pair between a CPU and a GPU across a PCIe, NVLink, or equivalent interconnect. The system maintains two independently trained directional codebooks, one for each traffic direction, each generated from a dedicated occurrence counter array that accumulates symbol pattern statistics for that direction without any shared training state. An encoder at each endpoint encodes outgoing protocol data units by substituting multi-byte symbol patterns with variable-length codewords assigned by the active directional codebook, embedding a codebook version number in each encoded frame header to enable correct decoding independent of concurrent version transitions. A compaction factor estimator evaluates the compression performance achievable at each of a plurality of candidate sourceblock lengths without generating any codebook, selecting the optimal length continuously. A codebook lifecycle manager governs codebook generation, staged deployment, automatic rollback, ramp-up bootstrap, and power-state adaptation. A pair codebook synchronization protocol coordinates version transitions between endpoints without interrupting the encoded data path..

According to a preferred embodiment, a computing system comprising at least one processor, a memory, and a plurality of programming instructions stored in a non-transitory medium that, when operating on the at least one processor, cause the computing system to: maintain a first occurrence counter array in memory that accumulates, for each distinct multi-byte symbol pattern observed in data transmitted from a central processing unit (CPU) to a graphical processing unit (GPU) across a PCIe, NVLink, or equivalent interface, a count of the number of times that symbol pattern has been observed in that direction; maintain a second occurrence counter array in memory that accumulates, for each distinct multi-byte symbol pattern observed in data transmitted from the GPU to the CPU across the same interface, a count of the number of times that symbol pattern has been observed in that direction; generate a first directional codebook by applying a codebook generation algorithm to the first occurrence counter array; generate a second directional codebook by applying the codebook generation algorithm independently to the second occurrence counter array, wherein the second directional codebook is generated and updated independently of the first directional codebook and shares no training state with the first directional codebook; encode each protocol data unit (PDU) transmitted from the CPU to the GPU by substituting, for each multi-byte symbol pattern in the PDU, the codeword assigned to that symbol pattern by the first directional codebook; encode each PDU transmitted from the GPU to the CPU by substituting, for each multi-byte symbol pattern in the PDU, the codeword assigned to that symbol pattern by the second directional codebook; and embed a codebook version number in the header of each encoded PDU identifying which version of the applicable directional codebook was used to encode that PDU.

According to an aspect of an embodiment, the programming instructions further cause the computing system to enforce a no-symmetry constraint such that the first directional codebook and the second directional codebook are at all times independently trained instances generated from independently accumulated occurrence statistics, and no codebook trained on one direction is used to encode or decode traffic in the other direction.

According to an aspect of an embodiment, the programming instructions further cause the computing system to: classify each outgoing CPU-to-GPU PDU into one of a plurality of traffic classes comprising at least a kernel launch descriptor class and a model weight tensor class, based on one or more header fields of the PDU; maintain a separate directional codebook for each traffic class in a codebook affinity table; and select, for encoding each outgoing PDU, the directional codebook associated with the traffic class assigned to that PDU.

According to an aspect of an embodiment, the programming instructions further cause the computing system to: assign each newly observed traffic flow that has not yet accumulated sufficient statistics to support a dedicated codebook to a general-purpose bootstrap codebook; and promote a flow to dedicated codebook status, and trigger generation of a dedicated directional codebook for that flow, when the flow's cumulative transmitted data volume exceeds a configurable threshold.

According to an aspect of an embodiment, the programming instructions further cause the computing system to coordinate each codebook version transition through a four-phase handshake comprising: transmitting, from the endpoint generating a new directional codebook, an announcement message carrying the new codebook version number, a scope identifier, a sourceblock length, and a cryptographic integrity tag; upon receipt of the announcement message at the peer endpoint, validating the cryptographic integrity tag, installing the new codebook in a shadow codebook table without activating it, and transmitting a readiness acknowledgment; upon receipt of the readiness acknowledgment, atomically activating the new codebook for all subsequent PDUs beginning at the next PDU boundary, with the first PDU encoded under the new codebook carrying the new version number in its header; and after a configurable retirement window, retiring the previous codebook version such that PDUs arriving after the retirement window carrying the old version number are treated as version-mismatch errors.

According to an aspect of an embodiment, the programming instructions further cause the computing system to: maintain, for each of a plurality of candidate sourceblock lengths, a corresponding occurrence counter array and an accumulator storing a running aggregate of the squared occurrence counts across all observed symbol patterns of that length; compute, for each candidate sourceblock length, a scalar compression performance estimate derived from the squared-occurrence accumulator and the total observation count, without generating any codebook for any candidate length; and select an optimal sourceblock length as the candidate length whose compression performance estimate indicates the greatest net compression benefit, and activate bypass mode if no candidate length yields a net compression benefit.

According to an aspect of an embodiment, the programming instructions further cause the computing system to: trigger a switch from a currently active sourceblock length to a candidate sourceblock length only when the compression performance improvement offered by the candidate exceeds a configurable switching threshold; apply a higher switching threshold when the candidate sourceblock length is longer than the currently active length than when it is shorter, thereby applying greater inertia against switches that would require a larger codebook and a longer ramp-up period; and enforce a minimum dwell period at each sourceblock length, equal to the time required to accumulate a full observation window at that length, before permitting any subsequent switch.

According to an aspect of an embodiment, the programming instructions further cause the computing system to: upon initialization of a directional codebook, immediately install a pre-seeded prior codebook selected from a stored library of prior codebooks organized by data class and sourceblock length, enabling compression of the first input PDU without waiting for an observation window to fill; and as observations accumulate, generate updated codebooks using a blended probability estimate for each symbol pattern that combines an empirically observed probability derived from accumulated observations with a prior probability from the pre-seeded prior codebook, wherein the weight assigned to the empirically observed probability increases and the weight assigned to the prior probability decreases as the number of accumulated observations increases toward a target observation window size, and wherein the blending transitions fully to the empirically observed probability once the target observation window size is reached.

According to an aspect of an embodiment, the programming instructions further cause the computing system to: receive, from a Global Compression Orchestrator, an occurrence counter summary from a donor compression domain identified by the Global Compression Orchestrator as having similar traffic characteristics to the directional codebook undergoing initialization; and incorporate the received occurrence counter summary as a high-weight prior component in the blended probability estimate, thereby materially reducing the number of observations required to achieve a fully converged codebook compared to initialization without the donor summary.

According to an aspect of an embodiment, the programming instructions further cause the computing system to: upon generation of a candidate directional codebook, apply a staged deployment process by initially encoding a configurable fraction of outgoing PDUs under the candidate codebook while encoding remaining PDUs under the incumbent codebook, each PDU carrying the version number of the codebook used to encode it; fully deploy the candidate codebook only upon confirming, over a configurable confirmation period, that the candidate codebook provides a materially greater compression benefit than the incumbent codebook and that the candidate codebook's mismatch rate is within acceptable bounds; and automatically reinstall the most recently superseded codebook version when, following full deployment, the observed compression performance deteriorates below the level achieved by the incumbent codebook at the time of deployment by more than a configurable amount sustained over a configurable period, the reinstallation performed by atomic pointer flip without interrupting in-flight PDUs.

According to an aspect of an embodiment, the programming instructions further cause the computing system to adapt directional codebook parameters in response to a current power state of the host processor, comprising: in a full-performance state, maintaining a maximum codebook entry count and operating at a full codebook retraining frequency; in a low-power state, reducing the active codebook entry count and reducing codebook retraining frequency to conserve power; in a sleep-adjacent state, freezing the observation window to prevent accumulation of new occurrence statistics while preserving the current codebook in memory for immediate use upon wake without requiring a ramp-up period; and in a deep-sleep state, checkpointing the current codebook and occurrence counter array to non-volatile storage before removing power from volatile memory, and restoring the checkpointed state upon wake within a bounded restoration time.

According to an aspect of an embodiment, the programming instructions further cause the computing system to: attach to each generated directional codebook a cryptographic integrity tag computed over the codebook content and associated metadata including at least the version number, sourceblock length, and issuer identifier; and prior to installing any received directional codebook, validate the cryptographic integrity tag and confirm that the version number of the received codebook is strictly greater than the highest version number previously installed from the same issuer, and reject without installation any codebook that fails either check.

According to an aspect of an embodiment, the programming instructions further cause the computing system to perform all compression performance estimation and codebook generation computations using only integer arithmetic and bit-shift operations, without any floating-point operation or lookup table, wherein each logarithmic computation is approximated using the position of the most significant bit of the integer operand.

### BRIEF DESCRIPTION OF THE DRAWING FIGURES

FIG. 1 is a block diagram illustrating an exemplary high-level system architecture of a computing system configured to implement a CPU–GPU bilateral compression pair, according to an embodiment.

FIG. 2 is a block diagram illustrating an exemplary internal architecture of the CPU-side compression engine, according to an embodiment.

FIG. 3 is a state machine diagram illustrating exemplary operational states and transitions of a codebook lifecycle manager, according to an embodiment.

FIG. 4 is a sequence diagram illustrating an exemplary multi-phase Pair Codebook Synchronization Protocol (PCSP) executed between the CPU-side PCSP sync engine, according to an embodiment.

FIG. 5 is a process flow diagram illustrating an exemplary method for staged rollout and automatic rollback executed by codebook lifecycle manager upon generation of a candidate directional codebook.

FIG. 6 is a block diagram illustrating an exemplary internal architecture of a compaction factor estimator and sourceblock length selector, shown together as the compaction factor estimator and sourceblock length selector, according to an embodiment.

FIG. 7 is a block diagram illustrating an exemplary internal architecture of a per-flow codebook selection engine, according to an embodiment.

FIG. 8 is a method flow diagram illustrating an exemplary end-to-end method of operating a CPU–GPU bilateral compression pair, according to an embodiment

FIG. 9 is a process flow diagram illustrating an exemplary rapid ramp-up bootstrap process executed by codebook lifecycle manager upon entry into bootstrap state of state machine.

FIG. 10 illustrates an exemplary computing environment on which an embodiment described herein may be implemented.

### DETAILED DESCRIPTION OF THE INVENTION

The inventor has conceived, and reduced to practice, a computing system implements a bilateral compression pair between a CPU and a GPU across a PCIe, NVLink, or equivalent interconnect. The system maintains two independently trained directional codebooks, one for each traffic direction, each generated from a dedicated occurrence counter array that accumulates symbol pattern statistics for that direction without any shared training state. An encoder at each endpoint encodes outgoing protocol data units by substituting multi-byte symbol patterns with variable-length codewords assigned by the active directional codebook, embedding a codebook version number in each encoded frame header to enable correct decoding independent of concurrent version transitions. A compaction factor estimator evaluates the compression performance achievable at each of a plurality of candidate sourceblock lengths without generating any codebook, selecting the optimal length continuously. A codebook lifecycle manager governs codebook generation, staged deployment, automatic rollback, ramp-up bootstrap, and power-state adaptation. A pair codebook synchronization protocol coordinates version transitions between endpoints without interrupting the encoded data path.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Conceptual Architecture

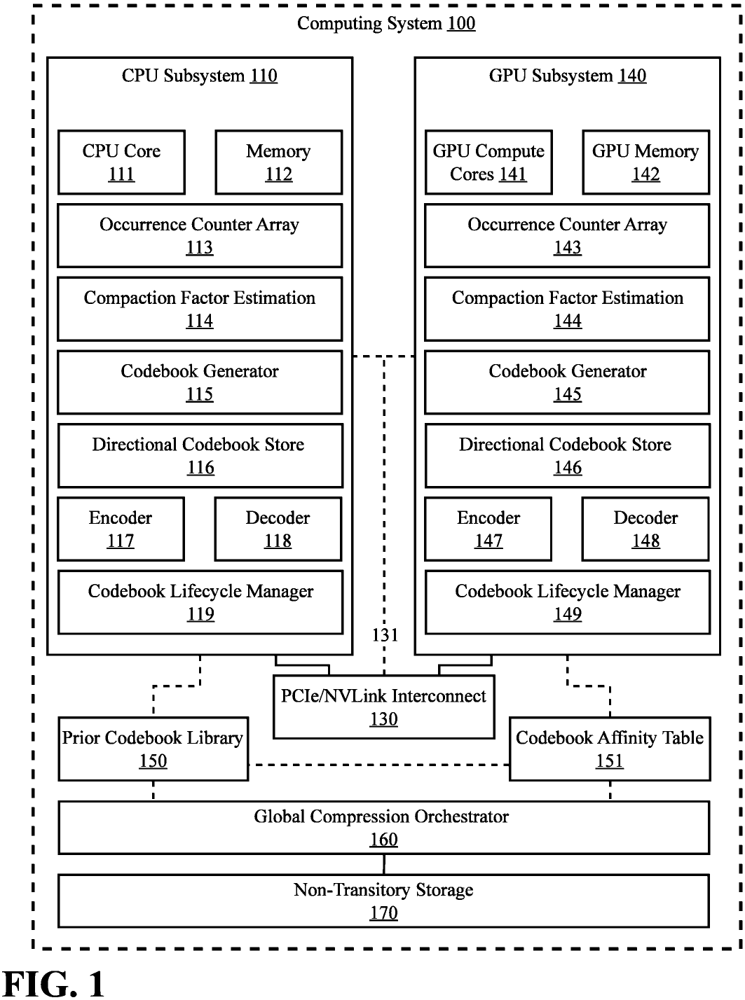

FIG. 1 is a block diagram illustrating an exemplary high-level system architecture of a computing system 100 configured to implement a CPU–GPU bilateral compression pair, according to an embodiment. The architecture depicted in FIG. 1 is illustrative of one embodiment and is not intended to be limiting; the functional elements shown may be implemented in whole or in part as dedicated hardware logic, firmware executing on a general-purpose processor, a combination of hardware and programmable logic, or as one or more processors executing programming instructions stored on a non-transitory computer-readable medium, as described further below.

Computing system 100 comprises, at a high level, a CPU subsystem 110, a GPU subsystem 140, an interconnect 130 coupling the two subsystems, a prior codebook library 150, a codebook affinity table 151, a Global Compression Orchestrator 160, and a non-transitory storage medium 170 on which a plurality of programming instructions is stored. When operating on at least one processor of computing system 100, the programming instructions stored in non-transitory storage 170 cause the computing system to perform the compression operations described herein. The architecture of FIG. 1 reflects the foundational design principle that data transmitted in the CPU-to-GPU direction and data transmitted in the GPU-to-CPU direction have statistically distinct byte-level distributions arising from the different roles of the two components, and that independent, directional compression management yields materially superior compression performance compared to any single shared codebook applied symmetrically to both directions.

CPU subsystem 110 comprises a CPU core 111 and a memory 112, together with a set of compression engine components that collectively manage the generation, maintenance, and application of a directional codebook for data transmitted from the CPU to the GPU. Specifically, CPU subsystem 110 includes an occurrence counter array 113, a compaction factor estimator 114, a codebook generator 115, a directional codebook store 116, an encoder 117, a decoder 118, and a codebook lifecycle manager 119. The occurrence counter array 113 accumulates, for each distinct multi-byte symbol pattern observed in data transmitted from the CPU to the GPU, a running count of the number of times that symbol pattern has been observed. The occurrence counter array 113 is continuously updated as data is processed, providing a real-time statistical profile of the CPU-to-GPU traffic stream. In preferred embodiments, occurrence counter arrays are maintained in parallel for a plurality of candidate source block lengths, enabling the system to evaluate and select the optimal source block length without generating a codebook for each candidate.

The compaction factor estimator 114 operates on the occurrence counter array 113 to compute a scalar compression performance estimate for each candidate source block length. This estimate is derived from the statistical distribution of observed symbol patterns and is computed without generating any codebook, enabling lightweight, low-latency evaluation of the expected compression benefit achievable at each candidate length. The codebook generator 115 receives the output of compaction factor estimator 114 and, upon determination that a new or updated codebook should be generated, produces a directional codebook by applying a codebook generation algorithm to the occurrence counter array 113. The resulting codebook is stored in directional codebook store 116, which maintains one or more active codebook versions for use by the encoder and decoder, as well as a shadow codebook table supporting hitless version transitions. In embodiments employing per-flow codebook selection, codebook store 116 may contain a plurality of codebooks each trained on a distinct traffic class within the CPU-to-GPU direction.

Encoder 117 applies the directional codebook stored in codebook store 116 to encode each protocol data unit (PDU) transmitted from the CPU to the GPU, substituting each multi-byte symbol pattern in the outgoing PDU with the codeword assigned to that pattern by the active codebook. Each encoded PDU carries a codebook version number in its header, enabling decoder 148 in GPU subsystem 140 to identify which codebook version applies to that PDU. Decoder 118 in CPU subsystem 110 correspondingly decodes PDUs received from the GPU by mapping codewords back to their corresponding symbol patterns using the directional codebook applicable to that traffic direction. The codebook lifecycle manager 119 governs the complete lifecycle of codebooks within CPU subsystem 110, including generation triggering, staged deployment, version management, rollback, and power-state adaptation, as described in further detail in connection with subsequent figures.

GPU subsystem 140 is structurally parallel to CPU subsystem 110 and comprises a GPU compute core 141 and GPU memory 142, together with a compression engine comprising an occurrence counter array 143, a compaction factor estimator 144, a codebook generator 145, a directional codebook store 146, an encoder 147, a decoder 148, and a codebook lifecycle manager 149. The compression engine components of GPU subsystem 140 operate independently of the corresponding components in CPU subsystem 110, maintaining their own occurrence statistics, generating their own directional codebook, and managing their own codebook lifecycle. No training state is shared between the two compression engines beyond the version synchronization information exchanged via the pair synchronization mechanism described herein. This independence is a deliberate architectural feature reflecting the empirically observed statistical asymmetry between the two traffic directions: the CPU-to-GPU direction carries primarily command structures, kernel launch descriptors, and model weight tensors, while the GPU-to-CPU direction carries inference output tensors, gradient data, and completion notifications, each exhibiting a distinct byte-level distribution that is best served by a codebook trained exclusively on that direction.

Interconnect 130 represents the physical and logical communication interface between CPU subsystem 110 and GPU subsystem 140, and may comprise a PCIe interface, an NVLink interface, or any functionally equivalent high-bandwidth interconnect. Encoded PDUs flow in both directions across interconnect 130, with each PDU carrying the version number of the codebook used to encode it. Interconnect 130 also carries the pair codebook synchronization protocol communications 131 by which the lifecycle managers of the two subsystems coordinate codebook version transitions. The synchronization protocol 131 ensures that no in-flight PDU is decoded using an incorrect codebook version by employing a multi-phase handshake in which a new codebook version is installed at the receiving endpoint prior to activation at the transmitting endpoint, with atomic activation deferred to a PDU boundary. In preferred embodiments, codebook version numbers are carried in vendor-defined fields of the PCIe or NVLink header, enabling version identification without out-of-band signaling.

Prior codebook library 150 is a stored collection of codebooks pre-trained for specific data classes, source block lengths, and architectural contexts. Upon initialization of a directional codebook—whether at system startup, following a data distribution shift, or following a source block length transition—the codebook lifecycle manager of the relevant subsystem selects a prior codebook from library 150 whose data class most closely matches the expected workload and installs it immediately as the active codebook, enabling compression of the first incoming PDU without waiting for the occurrence counter array to accumulate a full observation window. As live observations accumulate, the active codebook is progressively refined from the prior toward a fully data-driven codebook through a blended ramp-up mechanism in which the relative weight of the prior decreases and the weight of the live empirical distribution increases as the observation count approaches the target window size. Prior codebook library 150 is accessible to the lifecycle managers of both CPU subsystem 110 and GPU subsystem 140, though each subsystem selects and applies a prior appropriate to its respective traffic direction and data class. It will be appreciated that library 150 may be stored in any suitable memory, including non-transitory storage 170, and may be updated over time as new workload-specific priors become available.

Codebook affinity table 151 supports per-flow codebook selection within one or both subsystems. A traffic flow that has accumulated sufficient observations to warrant a dedicated codebook is assigned a codebook affinity entry mapping that flow's identifier to a specific codebook instance in the directional codebook store. Encoder 117 or encoder 147 consults codebook affinity table 151 to select the appropriate codebook for each outgoing PDU based on the flow to which that PDU belongs. Flows that have not yet accumulated sufficient statistics are assigned to a general-purpose bootstrap codebook until their cumulative data volume crosses a configurable threshold, at which point a dedicated codebook is generated and an affinity entry is created. Codebook affinity table 151 is updated by the control plane in response to per-flow compression performance telemetry reported by the lifecycle managers.

Global Compression Orchestrator (GCO) 160 is a control-plane component that monitors the compression performance of both subsystems, issues optimization signals to the codebook lifecycle managers 119 and 149 and facilitates coordinated codebook management across the computing system. GCO 160 communicates with the lifecycle managers via control-plane interfaces represented by the dashed lines in FIG. 1 and does not reside on the data path. In embodiments where the computing system operates as part of a larger heterogeneous fabric, GCO 160 may aggregate telemetry from a plurality of compression domains across multiple nodes and issue fabric-level optimization signals including domain shift signals, anticipatory pre-warm signals, and compression load-balancing signals. In the context of the present figure, GCO 160 is particularly relevant to the accelerated ramp-up function of prior codebook library 150: when a new workload is detected or anticipated, GCO 160 may identify a donor compression domain with similar traffic characteristics and provide its occurrence counter summary to the bootstrapping lifecycle manager as a high-weight prior, materially reducing the number of observations required to achieve a fully converged codebook. GCO 160 may be implemented as a software service executing on one or more processors of computing system 100 or on a separate management processor, and its presence is optional in embodiments that do not require fabric-level coordination.

Non-transitory storage 170 stores the plurality of programming instructions that, when operating on at least one processor of computing system 100, cause the system to perform the compression, codebook management, and synchronization operations described herein. Non-transitory storage 170 may comprise any suitable combination of volatile and non-volatile memory, including but not limited to SRAM, DRAM, NAND flash, NOR flash, and persistent memory technologies. The programming instructions stored in non-transitory storage 170 include instructions implementing all of the functional components depicted in FIG. 1, including but not limited to the occurrence counter accumulation functions of 113 and 143, the compaction factor estimation functions of 114 and 144, the codebook generation functions of 115 and 145, the encoding functions of 117 and 147, the decoding functions of 118 and 148, the lifecycle management functions of 119 and 149, and the synchronization protocol 131. It will be understood that the allocation of these functions to specific processors or memory regions within computing system 100 may vary across embodiments, and that functions described as residing in one subsystem may be distributed across multiple processors or co-located with functions described as residing in another subsystem, provided that the functional relationships depicted in FIG. 1 are preserved.

The solid lines in FIG. 1 represent data paths along which PDUs or codebook data flow during normal operation. The dashed lines represent control and management paths along which synchronization messages, telemetry reports, optimization signals, and prior codebook distributions are conveyed. This distinction is illustrative; in practice, control and data path communications may share a physical medium, and the separation shown in FIG. 1 reflects logical rather than necessarily physical separation. The arrangement of components depicted in FIG. 1 is exemplary, and one skilled in the art will recognize that the functional elements may be combined, subdivided, or reorganized without departing from the scope of the present disclosure.

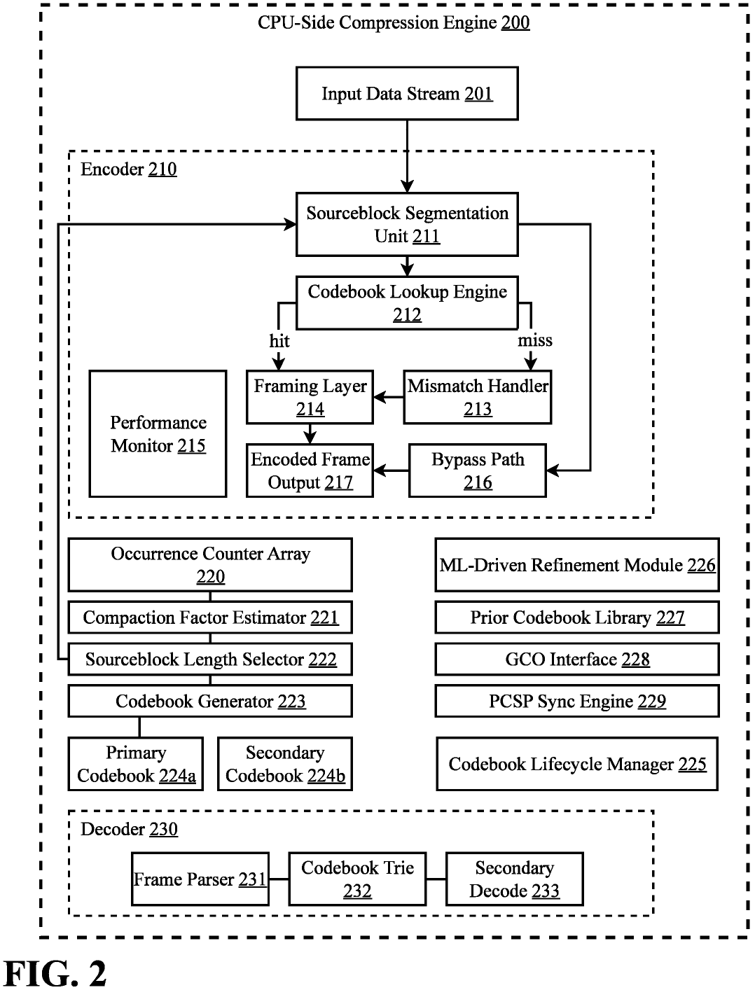

FIG. 2 is a block diagram illustrating an exemplary internal architecture of the CPU-side compression engine 200, according to an embodiment. The CPU-side compression engine 200 corresponds to and expands upon the CPU subsystem 110 depicted in FIG. 1, and comprises an encoder subsystem 210, an occurrence counter array 220, a compaction factor estimator 221, a source block length selector 222, a codebook generator 223, a directional codebook store 224, a codebook lifecycle manager 225, an ML-driven refinement module 226, a prior codebook library 227, a GCO interface 228, a PCSP sync engine 229, and a decoder subsystem 230. The arrangement and interconnection of these components is described in detail below. It will be understood that the functional elements shown in FIG. 2 may be implemented in hardware, firmware, software executing on one or more processors, or any combination thereof, and that the boundaries between components depicted in FIG. 2 are logical rather than necessarily physical.

Encoder subsystem 210 receives an input data stream (e.g., of raw protocol data units) 201 from the CPU core and is responsible for producing a compressed output stream for transmission across the interconnect to the GPU. Encoder subsystem 210 comprises a source block segmentation unit 211, a codebook lookup engine 212, a mismatch handler 213, a framing layer 214, a performance monitor 215, a bypass path 216, and an encoded frame output 217.

The source block segmentation unit 211 receives the input data stream 201 and partitions each incoming PDU into fixed-length symbol patterns, referred to as source blocks, of the currently selected source block length. The source block length applied by segmentation unit 211 is determined by source block length selector 222, which feeds the optimal length back to segmentation unit 211 via a feedback path as described herein. Segmentation unit 211 simultaneously presents each observed source block to the occurrence counter array 220 for statistical accumulation, providing the continuous flow of observation data from which all statistical estimates and codebook generation decisions are derived.

The codebook lookup engine 212 receives each sourceblock produced by segmentation unit 211 and presents it to the primary codebook stored in directional codebook store 224a. In preferred embodiments, the primary codebook table is implemented as a content-addressable memory or hash table supporting low-latency lookup. When the presented sourceblock matches an entry in the primary codebook, the lookup engine retrieves the corresponding codeword and its length and forwards them to framing layer 214 for inclusion in the output stream. When the presented sourceblock does not match any entry in the primary codebook, a condition referred to as a mismatch, the lookup engine signals mismatch handler 213.

The mismatch handler 213 encodes source blocks that are not present in the primary codebook using, for example, a secondary one-byte codebook maintained in directional codebook store 224b. Upon a mismatch, mismatch handler 213 emits a reserved mismatch escape code (e.g., mismatch codeword) followed by the byte-by-byte secondary encoding of the mismatched source block and forwards the resulting encoded sequence to framing layer 214. The mismatch escape code is unambiguously distinguishable from all primary codewords, enabling decoder subsystem 230 to recognize and correctly handle mismatch-encoded source blocks without ambiguity. The secondary codebook 224b is a complete one-byte codebook covering all possible single-byte values and is therefore guaranteed to encode any source block without itself producing a mismatch, ensuring that the hybrid encoding path always terminates successfully regardless of the statistical properties of the input data.

The framing layer 214 assembles the compressed output stream from the codewords and mismatch-encoded sequences produced by lookup engine 212 and mismatch handler 213 respectively. Each output frame produced by framing layer 214 may begin with a frame header that includes at least a compaction-present flag indicating whether the frame payload is compressed or has been forwarded uncompressed via bypass path 216, and a codebook version number identifying the version of the directional codebook used to encode the frame payload. The codebook version number in the frame header enables decoder subsystem 230 at the GPU to identify and apply the correct codebook version to each arriving frame independently, supporting in-flight frames encoded under different codebook versions during version transition periods. The encoded frame output 217 represents the compressed data stream delivered to the interconnect for transmission to the GPU subsystem.

The performance monitor 215 continuously measures compression performance metrics from the encoding data path, including, but not limited to, the instantaneous compaction factor derived from the current observation window, the mismatch rate representing the fraction of source blocks not found in the primary codebook, the encoding throughput, and the codebook hit rate. Performance monitor 215 exports these metrics to ML-driven refinement module 226 to inform codebook update recommendations, and to Global Compression Orchestrator (GCO) interface 228 to support fabric-level telemetry aggregation when the computing system is connected to a Global Compression Orchestrator. Performance monitor 215 additionally provides its mismatch rate measurement to codebook lifecycle manager 225, which can use this signal as one of the possible trigger conditions for initiating codebook generation.

The bypass path 216 provides a direct route from segmentation unit 211 to encoded frame output 217 that bypasses the compression encoding path entirely. Bypass path 216 may be activated when compaction factor estimator 221 determines that the current data distribution does not yield a net compression benefit—specifically, when the estimated compression performance indicates that the compressed output would be no smaller than the uncompressed input—or when the system is in a cold-start phase before sufficient observations have accumulated in occurrence counter array 220 to support reliable codebook generation. Bypass path 216 may also be activated by a directive from codebook lifecycle manager 225 in response to power management requirements or a rollback event. When bypass path 216 is active, framing layer 214 can be configured to set the compaction-present flag to the clear state in the frame header, enabling decoder subsystem 230 to pass the frame payload to its output without attempting decompression. Bypass path 216 may be activated and deactivated on a per-frame basis without any disruption to the encoding or decoding of subsequent frames, providing seamless, frame-by-frame adaptation to changing data compressibility conditions.

The occurrence counter array 220 maintains, for each distinct multi-byte symbol pattern of the currently active source block length observed in the CPU-to-GPU data stream, a running count of the number of times that pattern has been observed within the current observation window. In preferred embodiments, occurrence counter array 220 maintains parallel arrays for each candidate source block length under evaluation, enabling compaction factor estimator 221 to simultaneously evaluate the compression potential of multiple candidate lengths without requiring sequential passes through the data stream. The occurrence counter array 220 is updated continuously by source block segmentation unit 211as each source block is processed, providing a real-time statistical profile of the CPU-to-GPU traffic distribution.

The compaction factor estimator 221 operates on the occurrence counter array 220 to compute a scalar compression performance estimate for each candidate sourceblock length. This estimate is derived from an aggregated statistical measure of the observed symbol pattern frequencies—specifically, from a quantity that is monotonically related to the entropy of the observed distribution—and can be computed entirely from the occurrence counter array without generating any codebook for any candidate length. The ability to estimate the expected compression performance of a hypothetical codebook without generating that codebook distinguishes the present architecture from prior art systems, which require generating and testing one complete codebook per candidate length before selecting among them. Compaction factor estimator 221 updates its estimates continuously as new observations arrive, providing a low-latency signal that accurately tracks the evolving data distribution. Compaction factor estimator 221 additionally provides a bypass activation signal to bypass path 216 when its estimates indicate that no candidate source block length yields a net compression benefit for the current data distribution.

The source block length selector 222 receives the compression performance estimates computed by compaction factor estimator 221 for all candidate source block lengths and selects the optimal source block length as the candidate offering the greatest estimated compression benefit, subject to the constraint that a net benefit exists. In some implementations, source block length selector 222 applies an asymmetric hysteresis mechanism when evaluating candidate length transitions: a higher performance improvement threshold is required before switching to a longer source block length than before switching to a shorter one, reflecting the greater ramp-up cost associated with longer lengths. Source block length selector 222 also enforces a minimum dwell period at each selected length equal to the time required to accumulate a full observation window at that length, preventing repeated switching during periods when occurrence statistics for a newly selected length are still accumulating. The selected optimal length is provided to source block segmentation unit 211 via a feedback path, and to codebook generator 223 as the target source block length for the next codebook generation cycle.

The codebook generator 223 produces a new directional codebook upon receiving a generation trigger from source block length selector 222, codebook lifecycle manager 225, or ML-driven refinement module 226. Codebook generator 223 applies a codebook generation algorithm to the occurrence counter array 220 for the selected source block length, producing a prefix-free variable-length code in which more frequently observed symbol patterns are assigned shorter codewords. In preferred embodiments, codebook generator 223 implements a modified Shannon-Fano algorithm that guarantees the full binary tree property of the resulting codebook, meaning every possible codeword bit pattern of the maximum codeword length is assigned to exactly one symbol pattern, ensuring that decoder subsystem 230 requires no invalid-codeword detection logic. Codebook generator 223 performs all computations using integer arithmetic and bit-shift operations, without floating-point operations, enabling deployment on processors without hardware floating-point units. The generated codebook is provided to directional codebook store 224a and to codebook lifecycle manager 225 for staged deployment processing.

The directional codebook store 224 maintains the codebooks used by encoder subsystem 210 and decoder subsystem 230 for the CPU-to-GPU and GPU-to-CPU traffic directions respectively. Directional codebook store 224 comprises a primary codebook 224a and a secondary codebook 224b. Primary codebook 224a stores the variable-length entropy code generated by codebook generator 223 and maintains both an active codebook slot and a shadow codebook slot to support hitless version transitions: a new codebook version is written to the shadow slot by codebook lifecycle manager 225 and activated atomically by pointer flip at a PDU boundary, ensuring that no in-flight PDU is encoded or decoded under a partially installed codebook. Secondary codebook 224b is a fixed, complete one-byte codebook that is permanently resident in directional codebook store 224 and serves as the universal fallback encoding path for source blocks not matched by the primary codebook, as described above in connection with mismatch handler 213. Secondary codebook 224b does not require generation, distribution, or version management, as it covers all possible single-byte values by definition and is identical at all times at both the CPU-side encoder and the GPU-side decoder.

The codebook lifecycle manager 225 governs the complete lifecycle of codebooks within CPU-side compression engine 200, from generation triggering through staged deployment, version management, rollback, and power-state adaptation. Upon receiving a candidate codebook from codebook generator 223, codebook lifecycle manager 225 initiates a staged deployment process in which the candidate codebook is initially applied to a configurable fraction of outgoing PDUs while the incumbent codebook continues to serve the remaining PDUs. Each PDU carries the version number of the codebook used to encode it, enabling decoder subsystem 230 at the GPU to correctly decode PDUs encoded under either version during the mixed-version deployment period. Codebook lifecycle manager 225 monitors the compression performance achieved by the candidate codebook during the staged deployment period and advances to full deployment only upon confirming, over a configurable confirmation period, that the candidate provides a materially greater compression benefit than the incumbent and that the candidate's mismatch rate is within acceptable bounds. If these conditions are not met within a configurable timeout period, the candidate codebook is abandoned and the incumbent remains active. Following full deployment, codebook lifecycle manager 225 continues to monitor compression performance and triggers an automatic rollback, reinstalling the most recently superseded codebook version by atomic pointer flip, if the observed compression performance deteriorates below the pre-deployment level by more than a configurable threshold sustained over a configurable period. Codebook lifecycle manager 225 additionally adapts codebook parameters to the current power state of the host processor, reducing the active codebook entry count and retraining frequency in low-power states, freezing the observation window in sleep-adjacent states, and checkpointing the codebook and occurrence counter array to non-volatile storage in deep-sleep states for restoration upon wake.

The ML-driven refinement module 226 continuously analyzes the metrics exported by performance monitor 215 and the statistical distribution maintained in occurrence counter array 220 to recommend codebook management actions to codebook lifecycle manager 225 and codebook generator 223. Refinement module 226 may be implemented as a lightweight machine learning model, a rules-based statistical analyzer, a transformer-based or integrated architecture, or a hybrid architecture combining statistical preprocessing with a learned policy for update scheduling. Some exemplary recommended actions available to refinement module 226 include, without limit, triggering a new codebook generation cycle, recommending a change in source block length, recommending a reduction in codebook entry count, and triggering rollback to a previous codebook version. Refinement module 226 additionally implements an anomaly detection function that identifies statistically anomalous patterns in codebook usage (e.g., such as a sudden spike in mismatch rate inconsistent with recent distribution trends, or a codebook update request not accompanied by a valid cryptographic integrity tag) and, upon detection of an anomaly, directs codebook lifecycle manager 225 to suspend pending updates and revert to the pre-anomaly codebook version.

The prior codebook library 227 maintains a collection of codebooks pre-trained for specific data classes, traffic types, source block lengths, and architectural contexts, and provides pre-seeded prior codebooks to codebook lifecycle manager 225 for use during the ramp-up bootstrap phase. When a new directional codebook is initialized — whether at system startup, following a source block length transition, or following a major data distribution shift — codebook lifecycle manager 225 selects from prior codebook library 227 the prior codebook whose data class and source block length most closely match the expected workload, and installs it immediately as the active codebook to enable compression from the first input PDU without waiting for occurrence counter array 220 to accumulate a full observation window. As live observations accumulate, codebook generator 223 produces updated codebooks that progressively blend the prior probability estimates with the empirically observed distribution, with the weight assigned to the prior decreasing and the weight assigned to the live observations increasing as the observation count approaches the target window size, until the system operates fully on live data. Prior codebook library 227 is accessible to codebook lifecycle manager 225 and may be updated over time by GCO interface 228 with superior priors derived from donor compression domains identified by the Global Compression Orchestrator as having similar traffic characteristics to the CPU-to-GPU direction of the present computing system.

The GCO interface 228 provides the boundary between CPU-side compression engine 200 and an external Global Compression Orchestrator when the computing system operates as part of a larger heterogeneous fabric. GCO interface 228 can be configured to receive optimization signals from the Global Compression Orchestrator, including, but not limited to, domain shift signals directing codebook lifecycle manager 225 to begin accumulating statistics for an anticipated workload transition, anticipatory pre-warm signals providing donor occurrence counter summaries for accelerated ramp-up, and global optimization signals requesting adjustments to the locally optimal codebook configuration in the interest of globally optimal fabric compression performance, and delivers these signals to codebook lifecycle manager 225 for action. GCO interface 228 additionally exports compression performance telemetry collected by performance monitor 215, including the current compaction factor, mismatch rate, ramp-up completion fraction, and codebook version number, to the Global Compression Orchestrator at configurable reporting intervals. The presence of GCO interface 228 and the connection to an external Global Compression Orchestrator are optional; CPU-side compression engine 200 operates autonomously in standalone deployments in which no Global Compression Orchestrator is present.

The pair codebook synchronization protocol (PCSP) sync engine 229 implements the pair codebook synchronization protocol that coordinates codebook version transitions between codebook lifecycle manager 225 of the CPU-side compression engine 200 and the corresponding lifecycle manager of the GPU-side compression engine. When codebook lifecycle manager 225 generates a new directional codebook and advances it through staged deployment to the point of full activation, PCSP sync engine 229 executes a multi-phase handshake with the GPU-side lifecycle manager prior to activating the new codebook version at the encoder. This handshake ensures that the GPU-side decoder has received, validated, and installed the new codebook version in its shadow codebook table before the CPU-side encoder begins producing frames encoded under that version, guaranteeing that no in-flight frame arrives at the GPU-side decoder encoded under a version that the decoder has not yet installed. PCSP sync engine 229 incorporates retransmission logic to tolerate loss of individual handshake messages and does not require in-order delivery of handshake messages relative to the encoded data stream, as the codebook version number carried in each frame header provides sufficient information for the decoder to apply the correct codebook independently of message ordering.

The decoder subsystem 230 is the functional complement of encoder subsystem 210 and is responsible for decompressing PDUs received from the GPU subsystem across the interconnect. Decoder subsystem 230 may comprise a frame parser 231, a codebook trie 232, and a secondary decode path 233. Frame parser 231 reads the frame header of each arriving PDU to extract the compaction-present flag and the codebook version number. If the compaction-present flag indicates that the frame payload is uncompressed, as occurs when bypass path 216 of the GPU-side encoder was active for that frame, frame parser 231 passes the payload to the output without modification. If the compaction-present flag indicates compression, frame parser 231 verifies that the codebook version number in the frame header matches the version currently installed in codebook trie 232 and proceeds with decoding if the versions match. If the versions do not match, frame parser 231 signals a version-mismatch condition to PCSP sync engine 229 for remediation. Codebook trie 232 performs the reverse mapping from variable-length codewords to fixed-length source blocks by traversing a binary trie structure derived from the active directional codebook, producing the original source block at each leaf node reached. Upon recognition of a mismatch escape code in the incoming compressed stream, frame parser 231 transitions to secondary decode path 233, which applies the secondary one-byte codebook to decode the following secondary-encoded bytes and reconstruct the mismatched sourceblock, after which frame parser 231 returns to primary decode mode. Codebook trie 232 is supplied with the active codebook version from primary codebook 224a via directional codebook store 224, ensuring that the trie always reflects the version most recently activated by codebook lifecycle manager 225 through the shadow codebook pointer flip mechanism.

The specific arrangement and partitioning of components depicted in FIG. 2 is exemplary, and one skilled in the art will appreciate that the functional elements described herein may be combined, subdivided, reordered, or distributed across multiple processors or hardware blocks without departing from the scope of the present disclosure.

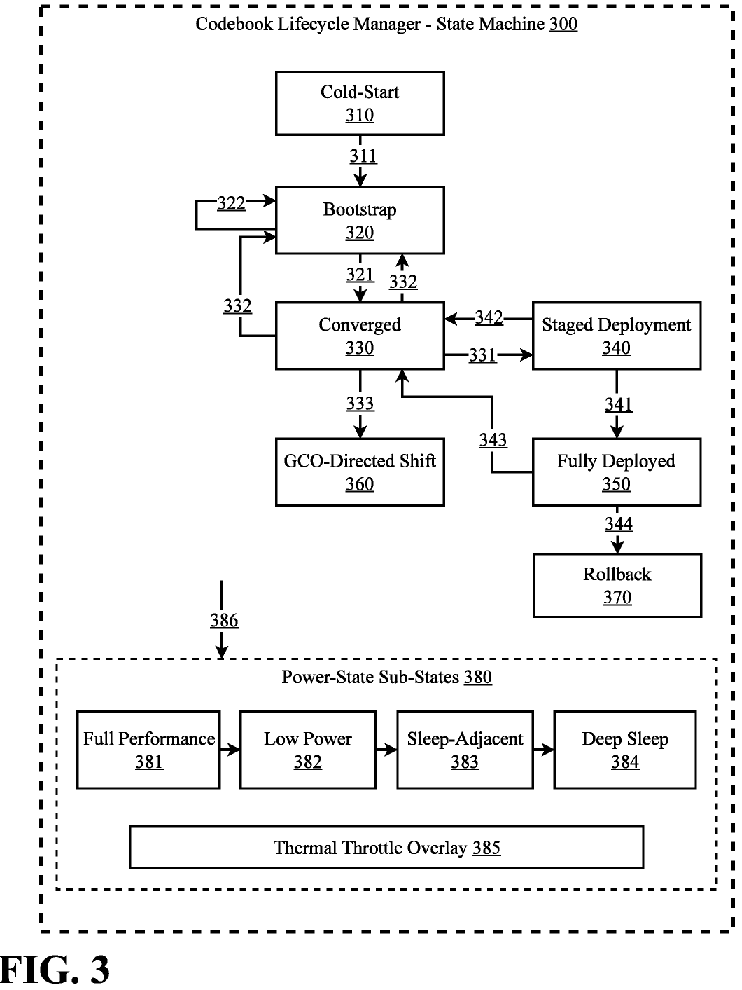

FIG. 3 is a state machine diagram illustrating exemplary operational states and transitions of a codebook lifecycle manager, according to an embodiment. The state machine 300 governs the complete lifecycle of a directional codebook from initial installation through ramp-up, convergence, update, staged deployment, and rollback, and further describes the power-state sub-states that apply in response to power management directives from the host processor. The states and transitions depicted in FIG. 3 are illustrative of one embodiment; the boundaries between states, the specific conditions governing each transition, and the actions performed upon entry to and exit from each state may vary across embodiments without departing from the scope of the present disclosure.

The state machine 300 is entered at system initialization and proceeds immediately to the cold-start state 310. Cold-start state 310 represents the condition in which the occurrence counter array 220 is empty and no live observation data has been accumulated. In cold-start state 310, a pre-seeded prior codebook selected from prior codebook library 227 is installed as the active codebook, enabling the encoder to begin compressing incoming PDUs from the first byte of input without requiring any observation window to be filled. The prior codebook installed in cold-start state 310 can be selected based on the data class and source block length most closely matching the expected workload, as determined from static configuration, a signal from a compute job scheduler, a seed broadcast from the Global Compression Orchestrator received via GCO interface 228, or a heuristic derived from traffic source and destination identifiers. Cold-start state 310 is a transient state; the lifecycle manager exits cold-start state 310 and transitions to bootstrap state 320 upon receipt of a workload class identification signal 311, which may be provided by any of the sources described herein. In embodiments in which the workload class is known at provisioning time, this transition may occur immediately upon system initialization such that cold-start state 310 is effectively instantaneous.

Bootstrap state 320 represents the ramp-up phase during which the active codebook is progressively refined from the pre-seeded prior toward a fully data-driven codebook as live observations accumulate in occurrence counter array 220. In bootstrap state 320, the codebook generator 223 produces updated codebooks at regular intervals—in preferred embodiments, at observation counts corresponding to one-quarter, one-half, three-quarters, and the full target observation window size—each regeneration incorporating a greater weight on the empirically observed symbol pattern distribution and a correspondingly lesser weight on the prior distribution. The blending of prior and live probabilities provides a smooth trajectory of compression performance through the ramp-up period, avoiding the abrupt performance discontinuity that would result from a hard switch from the prior codebook to a fully live-trained codebook at the end of the observation window. The bootstrap state 320 exports ramp-up status metrics (including, but not limited to, the current observation count, the ramp-up completion fraction, the current blended compaction factor, and the estimated time to full window) to performance monitor 215 and to GCO interface 228 for use by the Global Compression Orchestrator in prioritizing ramp-up assistance resources.

Bootstrap state 320 supports a self-transition 322 that is triggered upon receipt of a donor occurrence counter summary from the Global Compression Orchestrator via GCO interface 228. Upon receipt of such a summary, the lifecycle manager 225 incorporates the donor occurrence statistics as a high-weight prior component in the blended probability estimate used by codebook generator 223, replacing or supplementing the prior codebook from prior codebook library 227. The donor summary is derived from a compression domain identified by the Global Compression Orchestrator as having similar traffic characteristics to the directional codebook undergoing bootstrap, and its incorporation materially reduces the effective cold-start window—in preferred embodiments, from a full observation window to as few as one-tenth of that window—thereby materially reducing the duration of degraded compression performance during workload transitions. The self-transition 322 does not interrupt ongoing encoding or decoding operations; the updated blended codebook is installed via the shadow codebook pointer flip mechanism of primary codebook 224a, ensuring continuity of the data path throughout the ramp-up process.

The lifecycle manager 225 exits bootstrap state 320 and transitions to converged state 330 via transition 321 when a plurality of conditions are jointly satisfied: first, the accumulated observation count reaches the target observation window size such that the blending weight assigned to the live empirical distribution reaches its maximum value and the prior is no longer referenced; and second, the compaction factor estimated by compaction factor estimator 221 has stabilized, indicating that the data distribution is sufficiently stationary to support a reliable live-trained codebook. In preferred embodiments, stability is assessed by evaluating whether the rate of change of the compaction factor estimate over a configurable number of recent observation intervals falls below a configurable convergence threshold.

Converged state 330 is the nominal steady-state of the lifecycle manager 225 and represents the condition in which a fully live-trained, stable directional codebook is active, encoding operations are proceeding at optimal compression performance, and compression performance telemetry is being exported at the configured reporting interval to performance monitor 215 and, where applicable, to the Global Compression Orchestrator via GCO interface 228. In converged state 330, the lifecycle manager 225 continuously monitors the compaction factor estimate, the mismatch rate, and the recommendations of ML-driven refinement module 226 for conditions that warrant initiating a codebook update cycle.

Three transitions exit converged state 330. The first, transition 331, is a generation trigger that causes the lifecycle manager 225 to exit converged state 330 and enter staged deployment state 340. Transition 331 is fired when any of the following conditions are met: the compaction factor estimate has improved by more than a configurable threshold relative to the estimate that was current when the active codebook was generated, indicating that a newly generated codebook would materially outperform the incumbent; the mismatch rate has exceeded a configurable high-water-mark threshold, indicating significant drift between the active data distribution and the distribution on which the incumbent codebook was trained; or a minimum refresh interval has elapsed since the last codebook generation. Upon firing of transition 331, codebook generator 223 generates a candidate codebook from the current occurrence counter array 220 and provides it to lifecycle manager 225 for staged deployment processing, as described below in connection with staged deployment state 340.

The second transition from converged state 330, transition 332, returns the lifecycle manager to bootstrap state 320 upon detection of a major data distribution shift. A major distribution shift is identified when the compaction factor deteriorates by more than a configurable shift threshold sustained over a configurable detection period, indicating that the current codebook is so poorly matched to the current data distribution that a full ramp-up cycle, rather than a targeted codebook generation, is warranted. Transition 332 reflects the practical reality that workload transitions in heterogeneous computing environments can be sufficiently abrupt that incremental codebook update is less effective than a fresh bootstrap cycle seeded with an appropriate prior for the new workload class.

The third transition from converged state 330, transition 333, is triggered by receipt of a domain shift signal from the Global Compression Orchestrator via GCO interface 228 and causes the lifecycle manager 225 to enter GCO-directed shift state 360, described further below. Transition 333 enables the Global Compression Orchestrator to direct the lifecycle manager to begin preparing a new codebook for an anticipated workload transition before the transition has fully manifested in the local traffic stream, supporting anticipatory pre-warm behavior as described in connection with GCO-directed shift state 360.

Staged deployment state 340 represents the period during which a candidate codebook generated by codebook generator 223 is being evaluated against the incumbent codebook under live traffic conditions before full deployment is authorized. In staged deployment state 340, the lifecycle manager 225 instructs encoder 117 to apply the candidate codebook to a configurable fraction of outgoing PDUs (in preferred embodiments, an initial fraction of ten percent) while continuing to encode the remaining PDUs under the incumbent codebook. Each PDU carries the version number of the codebook used to encode it in its frame header, enabling decoder subsystem 230 at the GPU to correctly decode PDUs encoded under either the candidate or the incumbent version during the mixed-version deployment period without requiring any synchronization beyond the version number field. The lifecycle manager 225 monitors the empirical compression performance achieved by the candidate codebook on the fraction of PDUs to which it is applied, comparing this performance against that of the incumbent codebook on the same traffic.

Two transitions exit staged deployment state 340. Transition 341 advances the lifecycle manager to fully deployed state 350 when both of the following conditions are confirmed to have been sustained over a configurable confirmation period: first, the candidate codebook's compression performance is materially better than the incumbent codebook's by more than a configurable confirmation threshold; and second, the candidate codebook's mismatch rate is within acceptable bounds, confirming that the candidate is well-matched to the live data distribution. Transition 342 returns the lifecycle manager to converged state 330, abandoning the candidate codebook and leaving the incumbent active, when the confirmation conditions are not met within a configurable timeout period. The timeout-based abandonment of transition 342 provides a natural defense against codebook generation cycles that produce candidate codebooks that appear promising based on occurrence statistics but perform poorly under live encoding conditions.

Fully deployed state 350 represents the condition immediately following the commitment of a new codebook version to full deployment, in which all outgoing PDUs are encoded under the new codebook version, and the prior incumbent version has been retired to the history buffer of lifecycle manager 225. In fully deployed state 350, the lifecycle manager 225 continues to monitor compression performance closely for evidence that the new codebook is performing as expected under the full production traffic volume. Two transitions exit fully deployed state 350. Transition 343 advances the lifecycle manager back to converged state 330 when the compression performance of the newly deployed codebook is confirmed stable over a configurable stabilization period, completing the codebook update cycle. Transition 344 fires when the observed compression performance deteriorates below the pre-deployment level by more than a configurable rollback threshold sustained over a configurable rollback detection period, directing the lifecycle manager to enter rollback state 370.

GCO-directed shift state 360 represents the period during which the lifecycle manager 225 is accumulating occurrence statistics for a target traffic pattern specified by the Global Compression Orchestrator, in anticipation of a workload transition that has been signaled in advance by the Global Compression Orchestrator via GCO interface 228. In GCO-directed shift state 360, the lifecycle manager 225 continues to serve the current incumbent codebook for all outgoing PDUs, maintaining full compression performance for the current workload, while simultaneously accumulating occurrence statistics for the anticipated target workload using observation data directed to a separate accumulation buffer designated by the Global Compression Orchestrator. In preferred embodiments, the Global Compression Orchestrator accompanies the domain shift signal of transition 333 with the occurrence counter summary of a donor domain having similar traffic characteristics to the anticipated target workload, which the lifecycle manager 225 uses to seed the accumulation buffer as a high weight prior in the same manner as the GCO donor summary self-transition 322 of bootstrap state 320. GCO-directed shift state 360 exits via transition 361 when the accumulated occurrence statistics for the target workload are sufficient to generate a candidate codebook, at which point codebook generator 223 produces the candidate codebook and the lifecycle manager 225 transitions to staged deployment state 340 to evaluate and deploy the candidate under live conditions.

Rollback state 370 represents the condition in which a deterioration in compression performance following full deployment of a new codebook has been detected and the lifecycle manager 225 is reverting to the most recently superseded codebook version. The reversion is performed by an atomic pointer flip of primary codebook 224a from the newly deployed codebook version to the prior version retained in the history buffer of lifecycle manager 225, ensuring that no in-flight PDU is affected by the rollback and that encoding and decoding operations continue without interruption throughout the rollback process. In preferred embodiments, lifecycle manager 225 retains a configurable number of prior codebook versions in the history buffer to support sequential rollback in the event that multiple successive codebook generations produce underperforming codebooks. Upon entry to rollback state 370, the lifecycle manager 225 temporarily increases the minimum dwell period enforced by source block length selector 222 to prevent rapid successive codebook generation cycles that could cause oscillatory behavior, and signals ML-driven refinement module 226 to investigate the cause of the performance deterioration. The rollback event is logged with timestamp and performance metrics and, where applicable, reported to the Global Compression Orchestrator via GCO interface 228 as a domain health signal. Rollback state 370 exits via transition 371 upon confirmation that the prior codebook version has been successfully restored and is performing within acceptable bounds, returning the lifecycle manager 225 to converged state 330.

The lower portion of FIG. 3 depicts the power-state sub-states 380 of the lifecycle manager 225, which are accessible from any of the primary states described above in response to a power management signal 386 from the host processor's power management controller. Power-state sub-states 380 comprise various sub-states representing progressively deeper power reduction levels. Full-performance sub-state 381 corresponds to normal operation in which the directional codebook is fully populated to the maximum configured entry count and the ML-driven refinement module 226 operates at its full retraining frequency. Low-power sub-state 382 represents a reduced-power operating mode in which the active codebook entry count is reduced to a configurable fraction of the maximum, reducing the active power consumed by the codebook SRAM array, and the retraining frequency of ML-driven refinement module 226 is proportionally reduced to shed the associated processing load. The compression performance achievable in low-power sub-state 382 is lower than in full-performance sub-state 381 by an amount that depends on the shape of the underlying frequency distribution; distributions that are highly skewed toward a small number of dominant symbol patterns retain the majority of their compression benefit with a reduced codebook, while more uniform distributions experience proportionally greater degradation. Sleep-adjacent sub-state 383 represents a near-sleep operating mode in which the codebook SRAM is placed in retention mode with the current codebook preserved, the observation window of occurrence counter array 220 is frozen to prevent accumulation of stale statistics during the sleep period, and the encoding clock is gated. The codebook is available for immediate use upon wake from sleep-adjacent sub-state 383 without any ramp-up period, as the codebook content is preserved in retention SRAM throughout the sleep period. Deep-sleep sub-state 384 represents the deepest power reduction mode, in which the codebook and the contents of occurrence counter array 220 are checkpointed to non-volatile storage before power is removed from the SRAM array. Upon wake from deep-sleep sub-state 384, the checkpoint is restored from non-volatile storage and compression operations resume from the checkpointed state; in preferred embodiments, the checkpoint restore operation is bounded at under one millisecond for codebook arrays up to sixty-four kilobytes, enabling rapid resumption of compression following deep-sleep exit. The power-state transitions among sub-states 381 through 384 are driven by power management signals 386 from the host processor's power management controller; transitions toward deeper sleep states follow the leftward-to-rightward direction indicated in FIG. 3, and transitions toward higher performance states follow the rightward-to-leftward direction upon power restoration or wake.

In addition to the multiple power-state sub-states, FIG. 3 depicts a thermal throttle overlay 385 that applies independently of the current power sub-state. Thermal throttle 385 may be activated when the host processor's junction temperature exceeds a configurable thermal threshold and causes ML-driven refinement module 226 to reduce its retraining frequency by a configurable factor (e.g., a factor of four) thereby shedding the associated processing and power load from the thermal budget of the host processor. Encoder 117 and decoder subsystem 230 may continue to operate at full throughput during thermal throttle 385 using the current active codebook; only the generation of new candidate codebooks by codebook generator 223 may be throttled. Thermal throttle 385 is lifted when the junction temperature falls below the thermal threshold by a configurable hysteresis margin, preventing rapid oscillation of the throttle state at temperatures near the threshold.

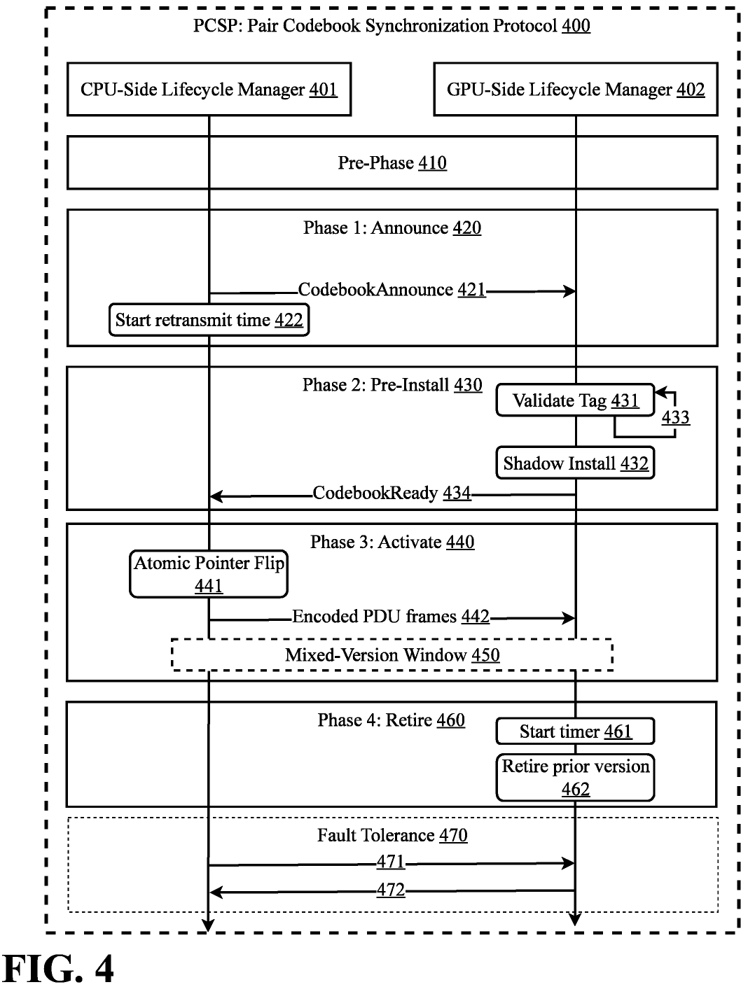

FIG. 4 is a sequence diagram illustrating an exemplary multi-phase Pair Codebook Synchronization Protocol (PCSP) 400 executed between the CPU-side PCSP sync engine 229, represented in FIG. 4 as CPU-side lifecycle manager 401, and the GPU-side lifecycle manager 402, which corresponds to GPU-side lifecycle manager 149 of FIG. 1. The PCSP 400 coordinates codebook version transitions across the interconnect 130 to ensure that no in-flight PDU is decoded using an incorrect codebook version. The protocol is initiated whenever the CPU-side codebook lifecycle manager 225 advances a candidate codebook from staged deployment state 340 to fully deployed state 350, as depicted in FIG. 3, and must complete successfully before the new codebook version is activated at the encoder.

Prior to initiating the protocol, pre-phase 410 represents the generation of the candidate codebook by codebook generator 223 and the computation of a cryptographic integrity tag over the codebook content and associated metadata, including the version number, source block length, scope identifier, and issuer identifier, as described in connection with codebook lifecycle manager 225 of FIG. 2.

In Phase 1: Announce 420, the CPU-side lifecycle manager 401 transmits a CodebookAnnounce message 421 to GPU-side lifecycle manager 402 across the interconnect. The CodebookAnnounce message 421 carries the new codebook version number, the scope identifier of the encoding scope, the sourceblock length of the new codebook, and the cryptographic integrity tag computed in pre-phase 410. Upon transmission of CodebookAnnounce message 421, the CPU-side lifecycle manager 401 starts a retransmit timer 422 and awaits acknowledgment from the GPU-side lifecycle manager 402. If no acknowledgment is received before retransmit timer 422 expires, the CPU-side lifecycle manager 401 retransmits CodebookAnnounce message 421 via a retransmit path in the fault tolerance section 470 and restarts the timer. This retransmission behavior ensures that the protocol completes correctly in the presence of message loss on the interconnect without requiring reliable delivery guarantees from the underlying transport.

In Phase 2: Pre-Install 430, the GPU-side lifecycle manager 402 receives the CodebookAnnounce message 421 and performs two sequential operations. First, the GPU-side lifecycle manager 402 validates the cryptographic integrity tag carried in the CodebookAnnounce message at step 431, confirming that the candidate codebook has not been modified in transit and that the version number is strictly greater than the highest version number previously installed, thereby providing replay protection. If integrity validation fails, the candidate codebook is rejected at step 433, the rejection is logged as a security event, and the GPU-side lifecycle manager 402 does not transmit a CodebookReady acknowledgment, causing the CPU-side retransmit timer 422 to eventually expire and the handshake to be re-initiated from Phase 1. If integrity validation succeeds, the GPU-side lifecycle manager 402 installs the new codebook into the shadow codebook slot of the GPU-side directional codebook store at step 432, without activating it, ensuring that the GPU-side decoder is prepared to decode frames encoded under the new version at the instant the CPU-side encoder activates it. Upon completing the shadow installation 432, the GPU-side lifecycle manager 402 transmits a CodebookReady acknowledgment message 434 to the CPU-side lifecycle manager 401, carrying the version number of the newly installed codebook as confirmation. A corresponding retransmit timer on the GPU side ensures that CodebookReady acknowledgment 434 is retransmitted if the CPU-side lifecycle manager 401 does not advance to Phase 3 within the timeout period.

In Phase 3: Activate 440, the CPU-side lifecycle manager 401 receives CodebookReady acknowledgment 434 and performs an atomic pointer flip 441 that activates the new codebook version in the CPU-side directional codebook store 224a for all subsequent outgoing PDUs, beginning at the next PDU boundary. Following atomic pointer flip 441, the CPU-side encoder 117 immediately begins encoding outgoing PDUs under the new codebook version, and each such PDU carries the new version number in its frame header as depicted by encoded PDU frames 442. Because the GPU-side decoder has already installed the new codebook in its shadow slot during Phase 2, it is prepared to decode frames encoded under the new version immediately upon their arrival, without any gap or reordering delay. Phase 3 additionally defines a mixed-version window 450 during which PDUs encoded under the prior codebook version that were already in flight on the interconnect at the time of atomic pointer flip 441 may continue to arrive at the GPU-side decoder. These in-flight prior-version frames are correctly decoded by the GPU-side decoder using the prior codebook version, which remains present in the GPU-side decoder table throughout the mixed-version window until it is retired in Phase 4. The coexistence of prior-version and new-version frames during the mixed-version window 450 is unambiguous because each frame carries its encoding version number in its frame header, enabling the GPU-side decoder to select the correct codebook for each arriving frame independently.

In Phase 4: Retire 460, the GPU-side lifecycle manager 402 starts a retirement timer 461 upon activation of the new codebook version, with the retirement timer duration set to at least the maximum round-trip time of a frame in the interconnect pipeline plus a configurable safety margin, ensuring that all in-flight prior-version frames have had sufficient time to arrive and be decoded before the prior codebook version is removed. Upon expiry of retirement timer 461, the GPU-side lifecycle manager 402 retires the prior codebook version from the decoder table at step 462, releasing the associated decoder table resources. Any frame arriving after retirement of the prior version that carries the old version number is treated as a version-mismatch error and is handled by the error recovery path of the PCSP sync engine 229.

The fault tolerance section 470 of FIG. 4 depicts the retransmission behavior that enables the PCSP 400 to complete correctly in the presence of message loss. Retransmit path 471 illustrates the retransmission of CodebookAnnounce message 421 by the CPU-side lifecycle manager 401 upon expiry of retransmit timer 422, and retransmit path 472 illustrates the retransmission of CodebookReady acknowledgment 434 by the GPU-side lifecycle manager 402 upon expiry of the corresponding GPU-side retransmit timer. In-order delivery of the PCSP handshake messages relative to the encoded data stream is not required; because each encoded PDU carries its version number in the frame header, the GPU-side decoder can correctly apply the appropriate codebook version to each arriving frame regardless of the relative ordering of PCSP control messages and encoded data frames on the interconnect.

Upon successful completion of all four phases, post-phase notation indicates that both the CPU-side encoder and the GPU-side decoder are operating exclusively under the new codebook version, the prior codebook version has been retired from the GPU-side decoder table, and the encoded data path has been uninterrupted throughout the entire protocol execution. The PCSP 400 depicted in FIG. 4 is representative of one embodiment, and one skilled in the art will appreciate that equivalent synchronization protocols achieving the same functional result, ensuring that no in-flight frame is decoded under an incorrect codebook version while maintaining uninterrupted data path operation, fall within the scope of the present disclosure.

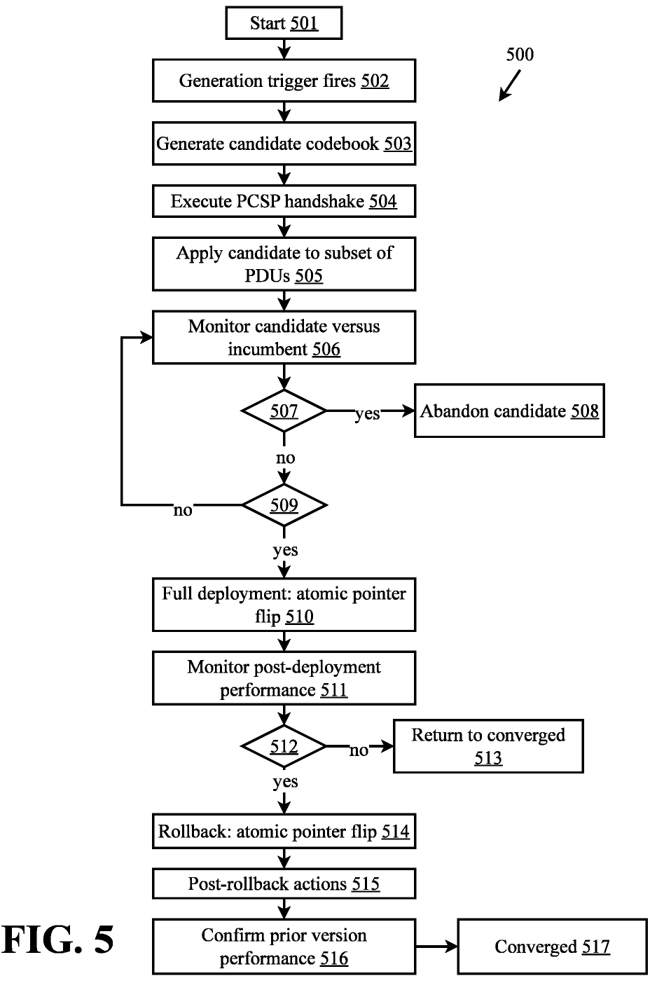

FIG. 5 is a process flow diagram illustrating an exemplary method for staged rollout and automatic rollback 500 executed by codebook lifecycle manager 225 upon generation of a candidate directional codebook. The method 500 corresponds to the transitions among converged state 330, staged deployment state 340, fully deployed state 350, and rollback state 370 of the state machine 300 depicted in FIG. 3, and expands those state transitions into the sequential decision logic and operational steps that govern each transition. The process 500 is entered from converged state 330 and returns to converged state 330 upon completion, regardless of whether the candidate codebook is successfully deployed or abandoned. The specific threshold values, timing parameters, and fraction values referenced herein are configurable parameters whose default values are illustrative and non-limiting.

According to an embodiment, the process begins at start step 501, representing the condition in which the codebook lifecycle manager 225 is in converged state 330 with a live-trained directional codebook active and compression performance telemetry being exported at the configured reporting interval. The process proceeds when a generation trigger fires at step 502. The generation trigger of step 502 is activated when any one of three conditions is satisfied: first, the compaction factor estimated by compaction factor estimator 221 has improved by more than a configurable threshold relative to the compaction factor that was current when the active codebook was generated, indicating that a newly generated codebook would materially outperform the incumbent; second, the mismatch rate reported by performance monitor 215 has exceeded a configurable high-water-mark threshold, indicating that the data distribution has drifted sufficiently from the distribution on which the incumbent codebook was trained to warrant a new codebook generation; or third, a configurable minimum refresh interval has elapsed since the last codebook generation, enforcing a minimum codebook refresh rate to prevent the active codebook from becoming arbitrarily stale relative to a slowly evolving data distribution. The generation trigger of step 502 may additionally be fired by an optimization signal received from the Global Compression Orchestrator via GCO interface 228, in which case the trigger carries the target workload class and, optionally, a donor occurrence counter summary as described in connection with GCO-directed shift state 360.

At step 503, codebook generator 223 generates a candidate codebook from the current state of occurrence counter array 220 for the sourceblock length currently selected by sourceblock length selector 222. The candidate codebook generation applies the codebook generation algorithm described in connection with codebook generator 223, producing a prefix-free variable-length code in which more frequently observed symbol patterns are assigned shorter codewords. Upon completion of codebook generation, codebook lifecycle manager 225 computes a cryptographic integrity tag over the candidate codebook content and associated metadata, including the new version number, sourceblock length, timestamp, and issuer identifier, for use in the PCSP handshake executed in the subsequent step. The candidate codebook version number assigned at step 503 is strictly greater than the highest version number previously assigned by the same issuer, satisfying the version monotonicity requirement that provides replay protection at the receiving endpoint.

At step 504, codebook lifecycle manager 225 directs PCSP sync engine 229 to execute the four-phase PCSP handshake described herein, transmitting the candidate codebook and its cryptographic integrity tag to the GPU-side lifecycle manager 402 and awaiting installation of the candidate codebook in the GPU-side shadow codebook slot. Step 504 ensures that the GPU-side decoder is prepared to decode frames encoded under the candidate codebook version before the CPU-side encoder begins applying the candidate codebook to any outgoing PDU. The process 500 does not advance beyond step 504 until the PCSP handshake completes successfully and the GPU-side lifecycle manager 402 has transmitted a CodebookReady acknowledgment confirming shadow installation, as described in connection with Phase 2: Pre-Install 430.

At step 505, codebook lifecycle manager 225 initiates staged deployment by instructing encoder 117 to apply the candidate codebook to a configurable fraction of outgoing PDUs, with the incumbent codebook continuing to serve the remaining PDUs. In preferred embodiments, the initial staged deployment fraction is ten percent of outgoing PDUs, selected uniformly at random or by flow identifier. Each PDU encoded at step 505 carries the version number of the codebook used to encode it in its frame header, enabling the GPU-side decoder to apply the correct codebook to each arriving PDU during the mixed-version staged deployment period without requiring any additional out-of-band signaling. The staged deployment fraction may be increased incrementally as monitoring at step 506 accumulates sufficient evidence of candidate codebook performance or may be maintained at the initial fraction for the duration of the confirmation period, depending on the deployment policy configured in codebook lifecycle manager 225.

At step 506, codebook lifecycle manager 225 monitors the compression performance achieved by the candidate codebook on the fraction of PDUs to which it is being applied, comparing this performance against that of the incumbent codebook on the same live traffic. The monitoring of step 506 measures two primary performance indicators: the compression benefit of the candidate codebook relative to the incumbent, assessed as the difference between the compaction factors achieved by the two codebooks on their respective fractions of the PDU stream; and the mismatch rate of the candidate codebook, which indicates the fraction of source blocks in the candidate-encoded PDUs that are not present in the candidate codebook and must be handled by mismatch handler 213 using secondary codebook 224b. These measurements are accumulated by performance monitor 215 and provided to codebook lifecycle manager 225 for evaluation against the confirmation conditions assessed at decision step 509.

At decision step 507, codebook lifecycle manager 225 evaluates whether the staged deployment timeout period has expired before the confirmation conditions of decision step 509 have been satisfied. If the timeout period has expired, corresponding to the Yes branch of decision step 507, the process proceeds to step 508, at which codebook lifecycle manager 225 abandons the candidate codebook, retains the incumbent codebook as the active codebook, and returns the lifecycle manager to converged state 330 at start step 501, leaving the data path unaffected. The timeout-based abandonment of step 508 reflects the determination that the candidate codebook has failed to demonstrate a material performance advantage over the incumbent codebook under live traffic conditions within the allotted evaluation period, and that continuing the staged deployment would not be productive. If the timeout period has not expired, corresponding to the No branch of decision step 507, the process proceeds to decision step 509.

At decision step 509, codebook lifecycle manager 225 evaluates whether both of the following confirmation conditions have been met and sustained over a configurable confirmation period: first, that the candidate codebook's measured compression benefit exceeds that of the incumbent codebook by more than a configurable confirmation threshold, confirming a material compression performance advantage; and second, that the candidate codebook's mismatch rate is within a configurable acceptable bound, confirming that the candidate codebook is well-matched to the current live data distribution and that the performance advantage observed during staged deployment is likely to be maintained under full deployment. If either or both of these conditions are not yet satisfied, corresponding to the No branch of decision step 509, the process returns to step 506 to continue monitoring, subject to the timeout check of decision step 507 at the next iteration. If both conditions are satisfied and have been sustained over the full confirmation period, corresponding to the Yes branch of decision step 509, the process advances to step 510.

At step 510, codebook lifecycle manager 225 executes full deployment of the candidate codebook by performing an atomic pointer flip of primary codebook 224a from the incumbent codebook version to the candidate codebook version. The atomic pointer flip of step 510 activates the new codebook for all subsequent outgoing PDUs beginning at the next PDU boundary, with the prior incumbent codebook version simultaneously moved to the history buffer maintained by codebook lifecycle manager 225 for potential use in rollback. In preferred embodiments, the history buffer retains a configurable number of prior codebook versions, enabling sequential rollback through multiple prior versions if successive candidate codebooks perform poorly after deployment. The atomic pointer flip of step 510 ensures that no in-flight PDU is affected by the version transition, as PDUs encoded before the pointer flip continue to carry the incumbent version number in their frame headers and are correctly decoded by the GPU-side decoder using the prior codebook version that remains present in the GPU-side decoder table until retired following the retirement window of Phase 4: Retire 460.

At step 511, codebook lifecycle manager 225 monitors the compression performance of the newly deployed codebook under full production traffic volume, comparing the observed compaction factor against the pre-deployment incumbent compaction factor recorded at the time of the full deployment decision of step 510. The monitoring of step 511 is conducted over a configurable post-deployment stabilization period to allow the observed compression performance to stabilize as all in-flight PDUs transition to encoding under the new codebook version and as the GPU-side decoder completes the retirement of the prior codebook version.

At decision step 512, codebook lifecycle manager 225 evaluates whether a performance deterioration has been detected and sustained, specifically whether the observed compaction factor has deteriorated below the pre-deployment incumbent compaction factor by more than a configurable rollback threshold sustained over a configurable rollback detection period. If no such deterioration is detected, corresponding to the No branch of decision step 512, the compression performance of the newly deployed codebook is confirmed stable, and the process proceeds to step 513, at which the codebook lifecycle manager 225 returns to converged state 330 with the newly deployed codebook active as the incumbent, completing the codebook update cycle. If a sustained performance deterioration exceeding the rollback threshold is detected, corresponding to the Yes branch of decision step 512, the process proceeds to rollback step 514.

At rollback step 514, codebook lifecycle manager 225 initiates the automatic rollback mechanism by performing a second atomic pointer flip of primary codebook 224a, reinstalling the most recently superseded codebook version from the history buffer as the active codebook. As with the pointer flip of step 510, the atomic pointer flip of rollback step 514 takes effect at the next PDU boundary without interrupting in-flight PDUs or requiring any reconfiguration of the GPU-side decoder, which continues to maintain both the rolled-back version and the failed new version in its decoder table until the appropriate retirement windows have elapsed. The rollback of step 514 is transparent to the encoded data path; from the perspective of the GPU-side decoder, the transition from the failed new codebook to the reinstated prior codebook is indistinguishable from any other codebook version transition, as each PDU continues to carry its encoding version number in its frame header.

At step 515, codebook lifecycle manager 225 performs a set of post-rollback management actions following the completion of rollback step 514. These actions include: increasing the minimum dwell period enforced by sourceblock length selector 222 to prevent rapid successive codebook generation cycles that could cause oscillatory behavior between generating and rolling back codebooks; signaling ML-driven refinement module 226 to investigate the cause of the performance deterioration that triggered the rollback, including whether the deterioration reflects a data distribution shift that would benefit from a different sourceblock length, a temporary anomaly that is expected to self-resolve, or a workload pattern that is not well-served by the current entries in prior codebook library 227; logging the rollback event with a timestamp, the performance metrics observed before and after rollback, and the version numbers of the affected codebook versions; and reporting the rollback event to the Global Compression Orchestrator via GCO interface 228 as a domain health signal, enabling the Global Compression Orchestrator to update its fabric-level compression performance map and adjust its optimization signals accordingly.

At step 516, codebook lifecycle manager 225 monitors the compression performance of the reinstated prior codebook version to confirm that it is performing within acceptable bounds following the rollback, verifying that the prior codebook version continues to provide the compression benefit that was observed before the failed candidate codebook was deployed. This confirmation step ensures that the rollback has been executed correctly and that the data path is operating normally under the reinstated prior codebook before the lifecycle manager returns to its steady-state monitoring behavior.

The process 500 concludes at converged state 517, representing the return of codebook lifecycle manager 225 to converged state 330 of the state machine 300 with the prior codebook version reinstated as the active incumbent codebook, compression performance telemetry being exported at the configured reporting interval, and the dwell timer and ML refinement module investigation initiated at step 515 proceeding in the background. The process 500 is representative of one embodiment, and one skilled in the art will appreciate that the specific sequence of steps, the number and nature of the confirmation conditions evaluated at decision steps 507, 509, and 512, and the specific post-rollback actions performed at step 515 may be varied without departing from the scope of the present disclosure.

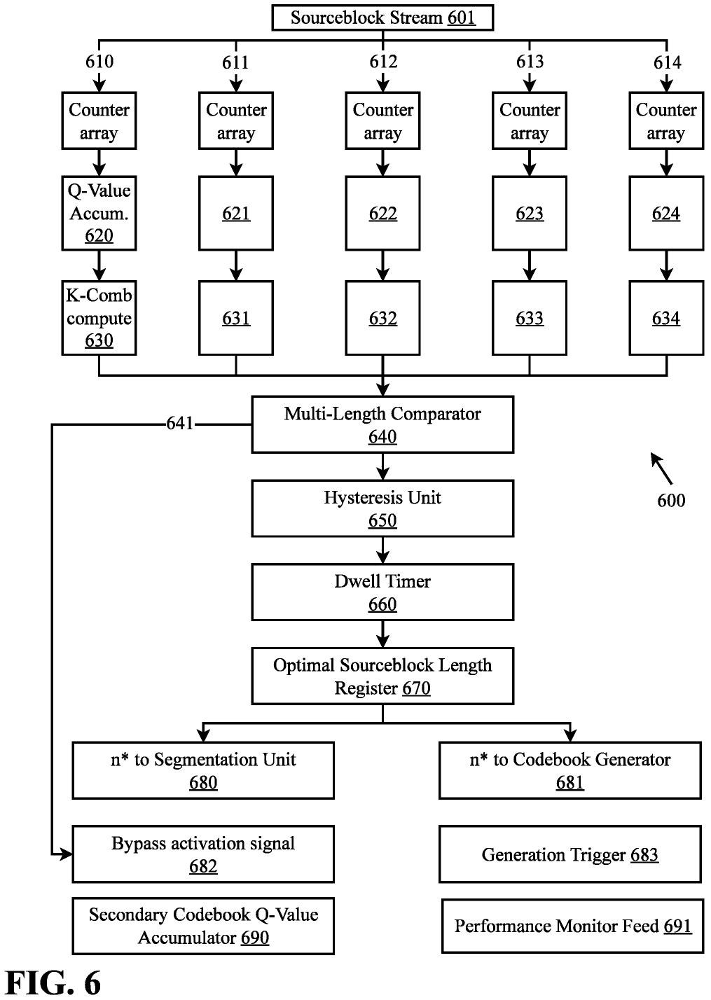

FIG. 6 is a block diagram illustrating an exemplary internal architecture of a compaction factor estimator 221 and sourceblock length selector 222 depicted in FIG. 2, shown together as the compaction factor estimator and sourceblock length selector 600, according to an embodiment. The illustrated architecture enables the ability to evaluate the expected compression performance of a given directional codebook at each of a plurality of candidate sourceblock lengths, and to select the optimal sourceblock length, without generating any codebook for any candidate length. The components depicted in selector 600 operate continuously and in parallel on the live CPU-to-GPU traffic stream, providing real-time compression performance estimates and length selection decisions that govern the behavior of encoder 117, codebook generator 223, bypass path 216, and codebook lifecycle manager 225. The arrangement and interconnection of components depicted is illustrative of one embodiment and is not intended to be limiting; equivalent implementations that produce the same functional outputs from the same statistical inputs fall within the scope of the present disclosure.

The sourceblock stream 601 represents the continuous flow of multi-byte symbol patterns produced by sourceblock segmentation unit 211 from the incoming CPU-to-GPU PDU data. Sourceblock stream 601 is fanned out in parallel to each of the five estimation lanes 610 through 614, each lane operating simultaneously and independently on the same incoming data stream. In preferred embodiments, the candidate sourceblock lengths evaluated by the five lanes are restricted to powers of two (e.g., one, two, four, eight, and sixteen, etc. bytes) corresponding to lanes 610, 611, 612, 613, and 614 respectively. This restriction to powers of two reduces the number of candidate lengths from the potentially larger set evaluated by systems to five fixed candidates, enabling all length-dependent division operations within each lane to be replaced by bit-shift operations consistent with the integer-only implementation described herein. The restriction does not materially reduce the quality of the optimal length selection in practice, as the optimal sourceblock length for real-world CPU-to-GPU traffic distributions is typically well-approximated by the nearest power of two to the natural autocorrelation length of the data.

Within each estimation lane, the incoming sourceblock stream is presented to a per-lane occurrence counter array that accumulates, for each distinct symbol pattern of that lane's candidate length observed in the data stream, a running count of the number of times that pattern has been observed within the current observation window. Each of the five estimation lanes maintains its own independent occurrence counter array operating at its respective candidate length; for example, the occurrence counter array of lane 610 accumulates counts of distinct one-byte patterns, the array of lane 611 accumulates counts of distinct two-byte patterns, and so forth through lane 614, which accumulates counts of distinct sixteen-byte patterns. The occurrence counter arrays are updated continuously as each incoming sourceblock is processed, providing a real-time statistical profile of the CPU-to-GPU traffic distribution at each candidate granularity. In preferred embodiments, the occurrence counter arrays are implemented as integer arrays in SRAM and are updated using only integer increment and decrement operations, with no floating-point arithmetic required at any stage of the accumulation process.

The per-lane Q-value accumulators 620, 621, 623, 624 maintain, for their respective candidate lengths, a running aggregate of the squared occurrence counts across all observed symbol patterns. Each Q-value accumulator 620 through 624 is updated incrementally as each new source block observation arrives and the oldest observation within the sliding window is retired, requiring only a small, fixed number of integer arithmetic operations per update regardless of the number of distinct symbol patterns in the occurrence counter array. This incremental update mechanism is the key property that enables the compaction factor estimation to track the evolving data distribution in real time at negligible computational cost, as it eliminates the need to recompute the aggregate from scratch across the entire occurrence counter array on each observation. The Q-value maintained by each accumulator 620 through 624 is a normalized aggregate that is monotonically related to the entropy of the observed symbol pattern distribution at the corresponding candidate length: a Q-value near its maximum indicates a highly skewed distribution in which a small number of patterns dominate and high compression is achievable, while a Q-value near its minimum indicates a near-uniform distribution in which compression yields little benefit.

The per-lane K-comb computation units 630, 631, 632, 633, 634 receive the Q-value from their respective accumulators 620 through 624 and the secondary codebook Q-value from secondary codebook Q-value accumulator 690 and compute a scalar combined compression performance estimate for their respective candidate lengths. The combined compression performance estimate computed by each K-comb computation unit 630 through 634 accounts for both the compression achievable by a primary codebook trained on the observed symbol pattern distribution at the candidate length and the compression achievable by the secondary one-byte fallback codebook on the fraction of source blocks that would not be matched by the primary codebook. This combined estimate is strictly more accurate than an estimate based solely on the primary codebook compression, as it correctly accounts for the mismatch overhead that would be incurred in practice when a fraction of incoming source blocks fall outside the primary codebook's coverage. According to an embodiment, K-comb computation units 630 through 634 derive the combined compression performance estimate entirely from the Q-value aggregates and the total observation count, without generating any codebook and without evaluating any candidate codebook against any portion of the data stream. All arithmetic performed within each K-comb computation unit 630 through 634 can be implemented using integer operations and bit-shift approximations of logarithmic computations, consistent with the integer-only implementation described herein.

The secondary codebook Q-value accumulator 690 maintains a running aggregate of the squared occurrence counts over the one-byte symbol distribution of the CPU-to-GPU traffic stream, independent of the candidate source block lengths evaluated by the five estimation lanes. The secondary codebook Q-value maintained by accumulator 690 is consumed by all five K-comb computation units 630 through 634 as the shared mismatch fallback contribution to each lane's combined compression performance estimate. The secondary codebook represented by accumulator 690 is a complete one-byte codebook covering all possible single-byte values and therefore incurs no mismatch penalty of its own; its Q-value reflects only the compression achievable on the byte-level distribution of the traffic stream and is independent of the candidate source block length of any particular estimation lane. In preferred embodiments, secondary codebook Q-value accumulator 690 is shared across all five estimation lanes to avoid redundant computation, as the one-byte distribution is the same regardless of the candidate length being evaluated.

The multi-length comparator 640 receives the combined compression performance estimates produced by all five K-comb computation units 630 through 634 and identifies the candidate source block length that yields the most favorable estimate, subject to the constraint that the estimate must indicate a net compression benefit, that is, that the expected compressed output size is smaller than the uncompressed input size for the corresponding candidate length. Multi-length comparator 640 performs this selection in a single comparison pass across the five estimates, requiring no iterative or sequential processing. When the candidate length identified by multi-length comparator 640 differs from the length currently stored in optimal source block length register 670, comparator 640 forwards the candidate length and its associated performance advantage to hysteresis unit 650 for evaluation of whether a switch is warranted. When all five candidate lengths fail the net compression benefit constraint, indicating that the current data distribution is incompressible at every candidate length, multi-length comparator 640 asserts bypass activation path 641, which routes the bypass activation signal to bypass path 216 of encoder 117, causing the encoder to forward incoming PDUs uncompressed until a subsequent evaluation cycle finds at least one candidate length that satisfies the net compression benefit constraint.

The hysteresis unit 650 governs whether a candidate length identified by multi-length comparator 640 as superior to the current length is permitted to trigger a switch. In some implementations, hysteresis unit 650 applies an asymmetric threshold policy in which a higher performance improvement margin is required to authorize a switch to a longer candidate sourceblock length than to authorize a switch to a shorter candidate sourceblock length. This asymmetry is deliberate: switching to a longer sourceblock length requires a larger codebook with more entries and a longer ramp-up period before the new length achieves its potential compression benefit, such that premature switching to a longer length on the basis of a marginal performance estimate could result in a period of degraded compression performance during the ramp-up window. By applying a higher authorization threshold for switches to longer lengths, hysteresis unit 650 ensures that only candidates offering a sufficiently clear performance advantage over the current length, one that is likely to be durable rather than transient, are permitted to trigger a switch in the lengthening direction, while more responsive switching is permitted in the shortening direction where the ramp-up cost is lower. Hysteresis unit 650 prevents oscillation between candidate lengths when their combined compression performance estimates are close to each other, a condition that commonly arises when the data distribution is near-uniform or is in transition between two statistical regimes.

The dwell timer 660 enforces a minimum dwell period at the current source block length before any switch authorized by hysteresis unit 650 is permitted to take effect. The minimum dwell period enforced by dwell timer 660 is set to the time required to accumulate a full observation window at the current source block length, ensuring that the occurrence counter arrays and Q-value accumulators for the current length have been populated with a statistically sufficient number of observations before any switch away from that length is considered. Dwell timer 660 is reset upon each switch of the current source block length and holds its output in the inhibit state while the timer is active, preventing switches regardless of the performance estimates produced by multi-length comparator 640 and hysteresis unit 650 during the dwell period. This behavior is particularly important immediately following a switch to a new length, when the occurrence counter arrays for the new length are still accumulating and the K-comb estimates for that length are based on insufficient observations and may therefore be unreliable. Once the dwell period has elapsed and the timer transitions to the permissive state, dwell timer 660 allows any switch authorized by hysteresis unit 650 to proceed to optimal source block length register 670.

The optimal source block length register 670 stores the currently active optimal source block length n*, which is updated by a permitted switch output from dwell timer 660. Optimal source block length register 670 provides n* to two consumers via dedicated output paths. The first output, n* to segmentation unit 680, delivers the current optimal length to source block segmentation unit 211 of FIG. 2, which uses it to partition incoming PDU data into source blocks of the appropriate length for encoding by encoder 117. The second output, n* to codebook generator 681, delivers the current optimal length to codebook generator 223 as the target source block length to be used in the next codebook generation cycle triggered by codebook lifecycle manager 225. When optimal source block length register 670 is updated with a new length following a permitted switch, both consumers receive the updated value simultaneously, ensuring that the segmentation unit and codebook generator always operate at the same source block length without requiring any explicit synchronization between them.

Bypass activation signal 682 is the output of bypass activation path 641 from multi-length comparator 640 and is delivered to bypass path 216 of encoder 117. When bypass activation signal 682 is asserted, encoder 117 forwards incoming PDUs uncompressed with the compaction-present flag cleared in each frame header, and the bypass activation signal remains asserted until a subsequent evaluation cycle by multi-length comparator 640 finds at least one candidate length for which the combined compression performance estimate satisfies the net compression benefit constraint, at which point bypass activation signal 682 is de-asserted and encoding under the selected codebook resumes.

Generation trigger 683 is an output derived from the compression performance estimates produced by K-comb computation units 630 through 634 and can be delivered to codebook lifecycle manager 225 to initiate a codebook generation cycle. Generation trigger 683 may be asserted when the combined compression performance estimate for the currently active source block length has improved by more than a configurable threshold relative to the estimate that was current when the active codebook was most recently generated, indicating that a newly generated codebook trained on the current occurrence statistics would materially outperform the incumbent codebook. Generation trigger 683 represents one of the multiple conditions that can activate the generation trigger of step 502 in the process flow of FIG. 5, the others being the mismatch high-water-mark condition reported by performance monitor 215 and the minimum refresh interval condition maintained by codebook lifecycle manager 225 itself.

The performance monitor feed 691 represents the export of the K-comb estimates and mismatch rate estimates produced by K-comb computation units 630 through 634 to performance monitor 215 and, in connected deployments, to GCO interface 228. Performance monitor 215 incorporates these estimates into the compression performance telemetry exported to the Global Compression Orchestrator at the configured reporting interval, enabling the Global Compression Orchestrator to assess the compression health of the CPU-to-GPU direction and issue optimization signals as appropriate. The K-comb estimates exported via performance monitor feed 691 additionally enable the Global Compression Orchestrator to identify the CPU-to-GPU compression domain as a candidate donor for ramp-up assistance to other compression domains with similar traffic characteristics, as described in connection with GCO-accelerated ramp-up in the bootstrap state 320.

The architecture 600 is representative of one embodiment, and one skilled in the art will appreciate that the number of parallel estimation lanes, the specific candidate sourceblock lengths evaluated by each lane, the specific threshold values applied by hysteresis unit 650, and the specific dwell period enforced by dwell timer 660 are all configurable parameters that may be varied to suit particular deployment requirements without departing from the scope of the present disclosure. In resource-constrained embodiments, the five parallel estimation lanes may be implemented as a single time-multiplexed lane that evaluates each candidate length sequentially within a single observation cycle, trading latency for reduced hardware resources while preserving the fundamental property that no codebook is generated during the estimation process.

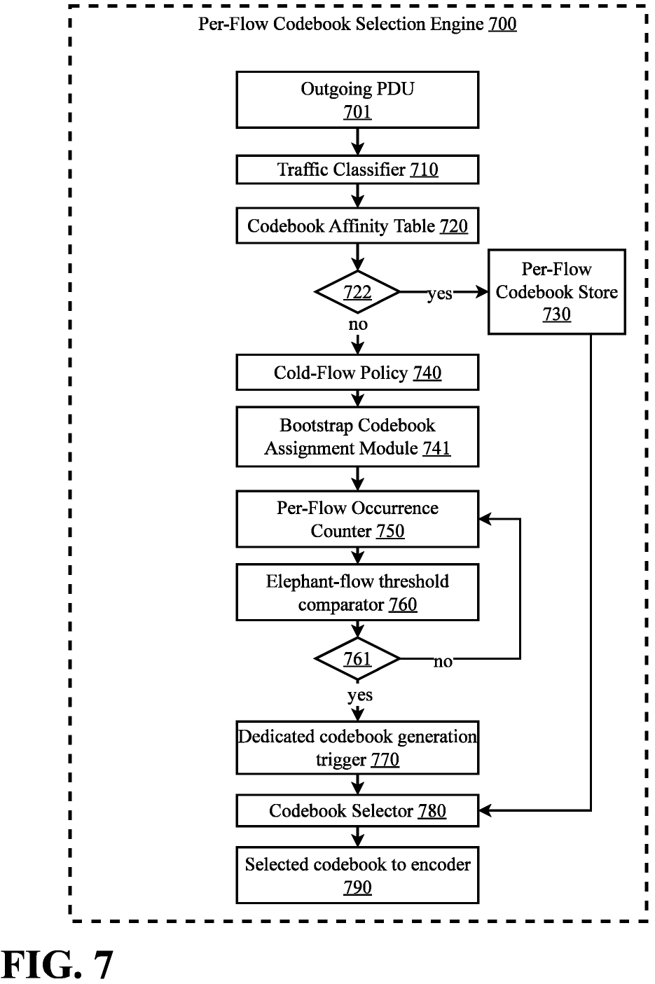

FIG. 7 is a block diagram illustrating an exemplary internal architecture of a per-flow codebook selection engine 700, according to an embodiment. The per-flow codebook selection engine 700 corresponds to the codebook affinity table 151 depicted in FIG. 1 and implements the per-flow codebook selection functionality described in connection with encoder 117 and codebook lifecycle manager 225 of FIG. 2. The per-flow codebook selection engine 700 addresses the practical observation that CPU-to-GPU traffic in heterogeneous computing environments comprises multiple concurrent traffic classes, including, but not limited to, kernel launch descriptors, model weight tensors, input activation batches, and memory management commands each exhibiting a distinct byte-level statistical distribution, that is best served by a dedicated directional codebook trained exclusively on that class, rather than a single shared codebook trained on the aggregate of all traffic classes. By maintaining separate directional codebooks for distinct traffic flows and selecting among them on a per-PDU basis, the per-flow codebook selection engine 700 enables the compression performance of each traffic class to approach the entropy-optimal limit for that class independently, without the performance degradation that would result from applying a codebook trained on a mixture of statistically dissimilar traffic classes to any individual class. The arrangement of components depicted in engine 700 is illustrative of one embodiment and is not intended to be limiting; equivalent implementations that achieve the same per-flow codebook selection function using different data structures, classification mechanisms, or promotion policies fall within the scope of the present disclosure.

The per-flow codebook selection engine 700 is entered upon receipt of an outgoing PDU 701 from the CPU core that is destined for transmission to the GPU subsystem across interconnect 130. Outgoing PDU 701 represents any protocol data unit generated by the CPU core for transmission in the CPU-to-GPU direction, including but not limited to PCIe transaction layer packets carrying kernel launch descriptors, command ring entries, model weight tensors, input activation batches, and memory management commands, as described herein.

Traffic classifier 710 receives outgoing PDU 701 and classifies it into one of a plurality of traffic classes by inspecting a configurable set of header fields within the PDU. In preferred embodiments, traffic classifier 710 inspects the PCIe requester identifier and function number for PCIe transaction layer packets, enabling classification by the source function within the CPU that generated the transaction and thereby distinguishing, for example, between transactions originating from a machine learning framework runtime and transactions originating from a graphics driver. In some implementations, traffic classifier 710 additionally supports classification based on a workload-type tag injected into the PDU header by an upstream software driver, enabling application-level classification that is more semantically precise than header field inspection alone. In embodiments where the CPU-to-GPU traffic carries network-layer payloads, traffic classifier 710 may additionally classify flows based on the five-tuple comprising source address, destination address, protocol identifier, source port, and destination port. The output of traffic classifier 710 is a flow identifier that uniquely identifies the traffic class and, where applicable, the specific application flow to which outgoing PDU 701 belongs. The specific header fields inspected by traffic classifier 710 are configurable and may be updated by the control plane in response to changes in the workload composition running on the computing system 100.

Codebook affinity table 720 receives the flow identifier produced by traffic classifier 710 and performs a lookup to determine whether an affinity table entry exists for that flow identifier. Codebook affinity table 720 is a hardware lookup table that maps each known flow identifier to a codebook index identifying the directional codebook currently assigned to serve that flow. In preferred embodiments, codebook affinity table 720 is implemented as a content-addressable memory or hash table supporting low-latency lookup at line rate. Codebook affinity table 720 is maintained by codebook lifecycle manager 225 via control plane update path, which carries affinity table updates issued by lifecycle manager 225 in response to per-flow compression performance telemetry, new elephant-flow promotions, and codebook version transitions. The control plane update path is a management interface that operates independently of the data path and does not introduce any latency into the per-PDU codebook selection process.

Decision 722 evaluates whether codebook affinity table 720 has returned a valid codebook index for the flow identifier of the current outgoing PDU 701. A valid entry is present in codebook affinity table 720 for flows that have previously been classified and assigned a codebook, whether a general-purpose bootstrap codebook assigned upon first observation of the flow or a dedicated per-flow codebook generated following elephant-flow promotion. When a valid affinity table entry is found, corresponding to the Yes branch of decision 722, the codebook index returned by codebook affinity table 720 is used to retrieve the corresponding directional codebook from per-flow codebook store 730, and the process proceeds directly to codebook selector 780 without traversing the cold-flow policy path. When no valid affinity table entry is found, corresponding to the No branch of decision 722, indicating that the flow has not previously been observed by the per-flow codebook selection engine 700, the process proceeds to cold-flow policy 740.

Per-flow codebook store 730 maintains the set of directional codebooks currently assigned to known flows, indexed by the codebook indices stored in codebook affinity table 720. Per-flow codebook store 730 may contain a plurality of dedicated per-flow codebooks, each generated by codebook generator 223 from the occurrence statistics accumulated by per-flow occurrence counter 750 for a specific elephant flow, as well as one or more bootstrap codebooks assigned to cold flows that have not yet been promoted to elephant-flow status. Per-flow codebook store 730 provides the codebook identified by the affinity table look up to codebook selector 780 for application to the current outgoing PDU 701 when the Yes branch of decision 722 is taken.

Cold-flow policy 740 is invoked when no affinity table entry is found for the flow identifier of the current outgoing PDU 701, indicating that the flow is being observed for the first time by the per-flow codebook selection engine 700. Cold-flow policy 740 performs two actions upon first observation of a new flow. First, it assigns the new flow to a general-purpose bootstrap codebook selected from prior codebook library 227, ensuring that the flow is encoded from its first PDU using a compression-capable codebook without waiting for per-flow occurrence statistics to accumulate. Second, cold-flow policy 740 initializes a per-flow byte counter for the new flow and creates a provisional entry in codebook affinity table 720 mapping the new flow's identifier to the bootstrap codebook index, so that subsequent PDUs belonging to the same flow are correctly identified by decision 722 and directed to the bootstrap codebook without re-invoking cold-flow policy 740. The provisional affinity table entry created by cold-flow policy 740 is subsequently updated by dedicated codebook generation trigger 770 upon promotion of the flow to elephant-flow status and completion of dedicated codebook generation, replacing the bootstrap codebook index with the index of the newly generated dedicated codebook.

Bootstrap codebook assignment 741 represents the installation of the general-purpose prior codebook selected by cold-flow policy 740 as the active codebook for the new flow. The bootstrap codebook assigned at step 741 is selected from prior codebook library 227 based on the traffic class identified by traffic classifier 710, enabling the initial bootstrap codebook to be at least approximately matched to the expected statistical distribution of the new flow even before any per-flow occurrence statistics have been accumulated. In preferred embodiments, the bootstrap codebook assigned at step 741 is the same prior codebook that would be selected for the cold-start state 310 of the lifecycle state machine 300 for the corresponding traffic class, providing consistency between the per-flow bootstrap behavior and the system-level bootstrap behavior.

Per-flow occurrence counter 750 accumulates the byte count and symbol pattern statistics for the flow as successive PDUs belonging to that flow are processed by the per-flow codebook selection engine 700. The cumulative byte count maintained by per-flow occurrence counter 750 represents the total number of bytes transmitted in PDUs belonging to this flow since the flow was first observed, and is the primary metric used by elephant-flow threshold comparator 760 to evaluate whether the flow has reached sufficient volume to warrant dedicated codebook generation. In addition to the cumulative byte count, per-flow occurrence counter 750 accumulates an occurrence counter summary (e.g., a compact representation of the per-flow symbol pattern frequency distribution) that is provided to dedicated codebook generation trigger 770 as the statistical basis for generating a dedicated per-flow codebook upon elephant-flow promotion. The occurrence counter summary accumulated by per-flow occurrence counter 750 is structurally equivalent to the occurrence counter array 220 described in connection with FIG. 2 and FIG. 6, operating at the sourceblock length currently selected by sourceblock length selector 222 for the traffic class of the corresponding flow.

Elephant-flow threshold comparator 760 continuously compares the cumulative byte count maintained by per-flow occurrence counter 750 against a configurable elephant-flow promotion threshold. The elephant-flow promotion threshold is a configurable parameter whose value may be set based on the characteristics of the deployment environment; in preferred embodiments the threshold ranges from one megabyte to one hundred megabytes depending on the expected distribution of flow sizes in the workload. The rationale for the elephant-flow threshold is the empirically observed concentration of traffic volume in a small fraction of flows: in typical CPU-to-GPU workloads, fewer than ten percent of flows by count account for more than ninety percent of traffic volume, such that concentrating dedicated codebook management resources on the flows that individually exceed the elephant-flow threshold captures the majority of the compression opportunity while limiting the number of dedicated codebooks that must be maintained in per-flow codebook store 730 and processed by codebook lifecycle manager 225.

Decision 761 evaluates whether the cumulative byte count for the current flow has exceeded the elephant-flow promotion threshold. When the threshold has not yet been exceeded, corresponding to the No branch of decision 761, the flow continues to be served by the bootstrap codebook assigned at step 741, and per-flow occurrence counter 750 continues to accumulate statistics for the flow as subsequent PDUs are processed. This accumulation loop continues until either the elephant-flow threshold is exceeded or the flow terminates, in which case its affinity table entry and per-flow occurrence counter are retired by codebook lifecycle manager 225 in accordance with a configurable flow inactivity timeout. When the elephant-flow threshold has been exceeded, corresponding to the Yes branch of decision 761, the flow is promoted to elephant-flow status and the process proceeds to dedicated codebook generation trigger 770.

Dedicated codebook generation trigger 770 initiates the generation of a dedicated directional codebook for the promoted elephant flow by signaling codebook generator 223 with the per-flow occurrence counter summary accumulated by per-flow occurrence counter 750. Codebook generator 223 generates a dedicated per-flow codebook from the per-flow occurrence statistics using the same modified Shannon-Fano codebook generation algorithm applied to all directional codebook generation in the system, as described in connection with codebook generator 223. The dedicated per-flow codebook generated by this process is optimized for the specific statistical distribution of the promoted flow, enabling it to achieve compression performance approaching the entropy-optimal limit for that flow's traffic class. Upon completion of dedicated codebook generation, dedicated codebook generation trigger 770 directs codebook lifecycle manager 225 to store the new dedicated codebook in per-flow codebook store 730 and to update the provisional affinity table entry in codebook affinity table 720 to reference the new dedicated codebook index in place of the bootstrap codebook index. Subsequent PDUs belonging to the promoted flow are therefore classified by traffic classifier 710, found in codebook affinity table 720 via the Yes branch of decision 722, and served directly by the dedicated codebook retrieved from per-flow codebook store 730, without traversing the cold-flow policy path.

Codebook selector 780 receives the codebook provided by per-flow codebook store 730 via the Yes branch of decision 722, or the bootstrap codebook provided by bootstrap codebook assignment 741 via the cold-flow policy path and selects the appropriate codebook for application to the current outgoing PDU 701. In the steady state following elephant-flow promotion, codebook selector 780 selects the dedicated per-flow codebook from per-flow codebook store 730 for all PDUs belonging to promoted flows. For PDUs belonging to flows that have not yet been promoted, including newly observed cold flows and flows that have not yet accumulated sufficient volume to exceed the elephant-flow threshold, codebook selector 780 selects the bootstrap codebook assigned at step 741.

The selected codebook output 790 delivers the codebook selected by codebook selector 780 to encoder 117 for application to the current outgoing PDU 701. Encoder 117 applies the selected codebook to each source block within outgoing PDU 701 using the codebook lookup engine 212, encoding the PDU under the per-flow optimized codebook and embedding the corresponding codebook version number in the frame header as described in connection with framing layer 214. The per-PDU codebook selection performed by per-flow codebook selection engine 700 is transparent to the remainder of the encoding pipeline; from the perspective of encoder 117, the selected codebook provided via output 790 is indistinguishable from the system-level directional codebook provided by directional codebook store 116, with the only difference being that the per-flow selected codebook may be one of a plurality of codebooks optimized for distinct traffic classes rather than a single codebook trained on the aggregate traffic distribution.

Per-flow telemetry represents the continuous export of per-flow compression performance metrics, including but not limited to, the per-flow compaction factor and per-flow mismatch rate measured by performance monitor 215 for each active codebook assignment, to codebook lifecycle manager 225 via the control plane. Codebook lifecycle manager 225 uses the per-flow telemetry of to maintain the accuracy of the codebook index assignments stored in codebook affinity table 720, updating affinity table entries when per-flow compression performance degrades below a configurable threshold indicating that the dedicated per-flow codebook has become stale relative to the current statistical distribution of the corresponding flow and that a new dedicated codebook generation cycle should be initiated. Per-flow telemetry is additionally exported to GCO interface 228 in deployments connected to a Global Compression Orchestrator, enabling the Global Compression Orchestrator to maintain a fabric-level view of per-flow compression performance across all CPU-to-GPU pairs in the computing fabric and to issue optimization signals targeting specific traffic classes or flows that exhibit persistent compression underperformance.

The per-flow codebook selection engine 700 is representative of one embodiment, and one skilled in the art will appreciate that the number of distinct traffic classes supported by traffic classifier 710, the specific header fields inspected for flow classification, the value of the elephant-flow promotion threshold applied by elephant-flow threshold comparator 760, and the number of dedicated per-flow codebooks maintained in per-flow codebook store 730 are all configurable parameters that may be varied to suit the characteristics of specific deployment environments without departing from the scope of the present disclosure. In resource-constrained embodiments, the number of simultaneously active dedicated per-flow codebooks may be limited by the available memory of per-flow codebook store 730, in which case codebook lifecycle manager 225 may implement a least-recently-used or least-compression-benefit eviction policy to retire the dedicated codebook of a lower-priority flow and reclaim its entry in per-flow codebook store 730 for allocation to a newly promoted elephant flow.

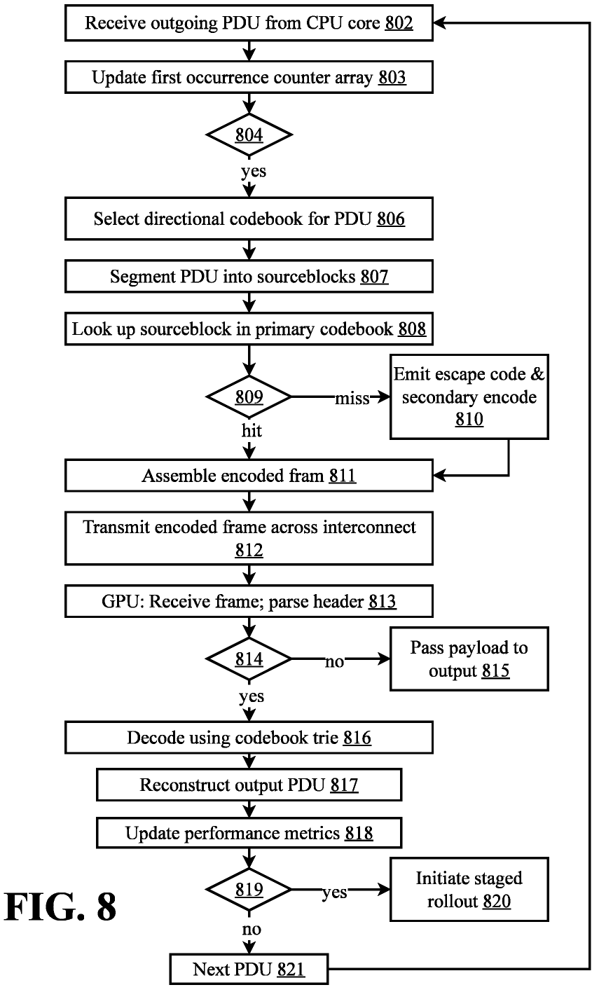

FIG. 8 is a method flow diagram illustrating an exemplary end-to-end method 800 of operating a CPU–GPU bilateral compression pair, according to an embodiment. The method 800 corresponds to the operation of computing system 100 as implemented by the programming instructions stored in non-transitory storage 170 and executing on at least one processor of computing system 100. The steps of method 800 collectively implement the functional behavior of CPU-side compression engine 200, the per-flow codebook selection engine 700, and the interconnect-spanning encoding and decoding operations described herein. The method 800 is a continuous per-PDU operation that executes for each outgoing PDU transmitted from the CPU core to the GPU subsystem and for each corresponding encoded frame received at the GPU subsystem, and repeats for each successive PDU as indicated by the loop path returning from step 821 to step 802. The specific components and reference numbers cited in the description of each method step correspond to the structural components described herein that implement that step, and the description of each step should be read in conjunction with the written descriptions of those figures. The method 800 is representative of one embodiment, and one skilled in the art will appreciate that the steps may be performed in different orders, that certain steps may be performed concurrently, and that additional steps may be interleaved without departing from the scope of the present disclosure.

The method 800 begins by representing the initialization of the CPU-side compression engine 200 in a state in which a directional codebook has been installed, either a pre-seeded prior codebook from prior codebook library 227 as described in connection with cold-start state 310 , or a live-trained codebook following a completed ramp-up cycle as described in connection with converged state 330, and the occurrence counter array 220 has been initialized, either to empty or to a bootstrapped state incorporating prior observation statistics.

At step 802, the CPU-side compression engine 200 receives an outgoing protocol data unit from the CPU core that is destined for transmission to the GPU subsystem across the PCIe, NVLink, or equivalent interconnect 130. The outgoing PDU received at step 802 may be any PDU generated by the CPU core for transmission in the CPU-to-GPU direction, including but not limited to PCIe transaction layer packets carrying kernel launch descriptors, command ring entries, model weight tensors, input activation batches, and memory management commands, as described in connection with the CPU-to-GPU direction of FIG. 1. In embodiments implementing the per-flow codebook selection engine 700, the outgoing PDU received at step 802 is simultaneously presented to traffic classifier 710 to initiate the per-flow codebook selection process that runs in parallel with the encoding path steps that follow.

At step 803, the computing system updates the first occurrence counter array maintained for the CPU-to-GPU traffic direction by incrementing the count associated with each distinct multi-byte symbol pattern observed within the outgoing PDU received at step 802. The updating of the first occurrence counter array at step 803 is performed by source block segmentation unit 211, which partitions the outgoing PDU into source blocks of the currently active optimal length and presents each source block to occurrence counter array 220 for count incrementation. The updated occurrence counter array 220 reflects the cumulative statistical distribution of all CPU-to-GPU symbol patterns observed since the current observation window was last reset, and its state at the time of each PDU's processing determines the compression performance estimate computed by compaction factor estimator 221 and source block length selector 222 on a continuous basis. Step 803 is performed for every outgoing PDU regardless of whether the PDU is subsequently encoded or forwarded uncompressed via the bypass path, ensuring that the occurrence counter array 220 always reflects the true statistical distribution of the CPU-to-GPU traffic stream including PDUs that may not have been compressible under the current codebook.

Following step 803, the method evaluates at decision step 804 whether the current data distribution yields a net compression benefit at the currently active optimal source block length. This evaluation is performed by compaction factor estimator 221 and multi-length comparator 640, which continuously assess whether the combined compression performance estimate for the currently active length indicates that the expected compressed output size is smaller than the uncompressed input size. When the evaluation at decision step 804 determines that no net compression benefit is achievable, corresponding to the No branch of decision step 804, which arises when the data distribution is sufficiently uniform at all candidate source block lengths that compression would expand rather than reduce the data volume, the method proceeds to step 805. At step 805, the computing system forwards the outgoing PDU uncompressed via bypass path 216, setting the compaction-present flag in the frame header to the clear state to signal to the GPU-side decoder that the frame payload is uncompressed and should be passed to the output without any decompression attempt. The bypass path of step 805 is activated and deactivated on a per-PDU basis without any disruption to the processing of subsequent PDUs, enabling the method to resume compression immediately upon the next evaluation at decision step 804 finding that a net compression benefit has been restored. Following step 805, the method rejoins the main flow at the interconnect transmission step 812, bypassing all encoding steps.

When the evaluation at decision step 804 determines that a net compression benefit is achievable, corresponding to the Yes branch of decision step 804, the method proceeds to step 806, at which the computing system selects the directional codebook to be applied to the encoding of the current outgoing PDU. In embodiments implementing the per-flow codebook selection engine 700, the codebook selected at step 806 is determined by codebook selector 780 based on the result of the affinity table lookup performed by codebook affinity table 720 for the flow identifier assigned by traffic classifier 710. In embodiments not implementing per-flow codebook selection, the codebook selected at step 806 is the currently active directional codebook stored in primary codebook 224a of directional codebook store 224. In either case, the codebook selected at step 806 is identified by its current version number, which will be embedded in the frame header at step 811 to enable the GPU-side decoder to apply the correct codebook to the arriving encoded frame.

At step 807, the computing system segments the outgoing PDU into a sequence of source blocks of the currently active optimal source block length n* maintained by optimal source block length register 670. Segmentation is performed by source block segmentation unit 211, which partitions the PDU on aligned boundaries such that each source block begins at a byte offset that is a multiple of n* from the start of the PDU. The optimal source block length n* applied at step 807 is the length most recently output by source block length selector 222 based on the continuous multi-length compression performance estimation performed by compaction factor estimator 221. In embodiments in which the PDU length is not an exact multiple of n*, the final partial source block at the PDU boundary is handled by one of the partial-block encoding policies described in connection with framing layer 214, including passthrough of the partial block uncompressed, zero-padding of the partial block to length n*, or byte-by-byte encoding of the partial block using secondary codebook 224b.

At step 808, the computing system presents each sourceblock produced by step 807 to the primary codebook stored in directional codebook store 224a via codebook lookup engine 212, performing a lookup to determine whether the sourceblock is present in the primary codebook. In preferred embodiments the primary codebook lookup is performed using a content-addressable memory or hash table supporting constant-time lookup latency. The outcome of the lookup at step 808 is evaluated at decision step 809, which distinguishes between a primary codebook hit, in which the presented sourceblock matches an entry in the primary codebook, and a primary codebook miss, in which the presented sourceblock is not present in the primary codebook.

When a primary codebook miss is detected at decision step 809, corresponding to the Miss branch, the method proceeds to step 810, at which mismatch handler 213 encodes the mismatched source block using the secondary one-byte codebook maintained in secondary codebook 224b of directional codebook store 224. At step 810, mismatch handler 213 emits a reserved mismatch escape code followed by the byte-by-byte secondary encoding of the mismatched source block, and forwards the resulting encoded sequence to framing layer 214 for inclusion in the output frame. The mismatch escape code emitted at step 810 is unambiguously distinguishable from all primary codewords in the active directional codebook, enabling the GPU-side decoder to recognize and correctly handle the secondary-encoded source block at decoding step 816 without ambiguity. Following step 810, the method rejoins the main encoding path at step 811.

When a primary codebook hit is detected at decision step 809, corresponding to the Hit branch, codebook lookup engine 212 retrieves the codeword assigned to the matched source block and its length from the primary codebook and forwards them to framing layer 214 for inclusion in the output frame. The method then proceeds directly to step 811.

At step 811, framing layer 214 assembles the encoded frame from the codewords produced by the primary codebook hit path and the escape-coded sequences produced by the mismatch handler path of step 810. The encoded frame assembled at step 811 includes a frame header containing at least a compaction-present flag set to the active state, indicating that the frame payload is compressed, and a codebook version number identifying the specific version of the directional codebook used to encode this frame. The codebook version number embedded in the frame header at step 811 is the version number of the codebook selected at step 806 and enables the GPU-side decoder to identify and apply the correct codebook version to the arriving frame at decoding step 816 independently of any out-of-band signaling. The compaction-present flag and version number together provide the GPU-side decoder with all information necessary to correctly decode the frame regardless of whether other concurrent frames on the interconnect were encoded under different codebook versions, supporting the mixed-version operation described in connection with the mixed-version window 450.

At step 812, the computing system transmits the encoded frame assembled at step 811, or the uncompressed frame forwarded at step 805, across interconnect 130 to the GPU subsystem. Step 812 represents the handoff from the CPU-side compression engine 200 to the physical interconnect 130 and marks the boundary between the CPU-side encoding operations of steps 802 through 811 and the GPU-side decoding operations of steps 813 through 817.

Following transmission at step 812 and the corresponding reception at the GPU subsystem, the method crosses the interconnect boundary indicated in FIG. 8, and the GPU-side decoding operations begin at step 813. At step 813, the GPU-side decoder subsystem 230 receives the encoded frame transmitted at step 812 and frame parser 231 reads the frame header to extract the compaction-present flag and the codebook version number. Decision step 814 evaluates the compaction-present flag extracted at step 813. When the compaction-present flag is in the clear state, corresponding to the No branch of decision step 814, indicating that the frame was forwarded via bypass path 216 at step 805, the method proceeds to step 815, at which frame parser 231 passes the frame payload directly to the GPU-side output without any decompression processing. Following step 815, the method rejoins the main flow at step 817 for PDU reconstruction. When the compaction-present flag is in the active state, corresponding to the Yes branch of decision step 814, indicating that the frame payload is compressed, the method proceeds to step 816.

At step 816, the GPU-side decoder subsystem 230 decodes the compressed frame payload using codebook trie 232, which performs the reverse mapping from the variable-length codewords in the compressed frame payload back to the fixed-length source blocks of the original PDU. Codebook trie 232 traverses the binary trie representation of the active directional codebook version identified by the version number extracted at step 813 bit-by-bit until a leaf node is reached at each codeword boundary, outputting the corresponding source block at each leaf. When a mismatch escape code is encountered in the compressed frame payload during the traversal of step 816, frame parser 231 transitions to secondary decode path 233, which applies secondary codebook 224b to decode the following secondary-encoded bytes and reconstruct the mismatched source block, after which the traversal of codebook trie 232 resumes for the remainder of the compressed frame payload.

At step 817, the decoded source blocks produced by step 816, together with any uncompressed payload passed through at step 815, are assembled by the source block reconstruction unit of decoder subsystem 230 into the reconstructed output PDU, which is then delivered to the GPU compute cores 141 for processing. The reconstructed output PDU delivered at step 817 is a lossless reconstruction of the original outgoing PDU received at step 802, with all source blocks restored to their original multi-byte symbol pattern values regardless of whether they were encoded via the primary codebook hit path, the mismatch handler path of step 810, or the bypass path of step 805.

At step 818, performance monitor 215 updates the compression performance metrics for the CPU-to-GPU direction based on the encoding operations performed in the current PDU processing cycle, including the instantaneous compaction factor derived from the ratio of compressed to uncompressed output size for the current PDU, the mismatch rate representing the fraction of source blocks handled by step 810 rather than the primary codebook hit path, and the codebook hit rate. Performance monitor 215 additionally evaluates whether any of the generation trigger conditions described in connection with step 502 have been satisfied, incorporating the updated metrics from the current PDU processing cycle into the trigger evaluation. The updated metrics and trigger evaluation results are exported to codebook lifecycle manager 225, ML-driven refinement module 226, and GCO interface 228 for ongoing codebook management and telemetry reporting as described in the written descriptions of those components.

Decision step 819 evaluates the outcome of the generation trigger assessment performed at step 818. When the generation trigger conditions are not satisfied, corresponding to the No branch of decision step 819, no codebook update is initiated and the method proceeds to step 821. When one or more generation trigger conditions are satisfied, corresponding to the Yes branch of decision step 819, the method proceeds to step 820, at which codebook lifecycle manager 225 initiates the staged rollout process described herein, beginning with the generation of a candidate codebook by codebook generator 223 at step 503. The staged rollout process initiated at step 820 executes concurrently with the continued per-PDU encoding and decoding operations of method 800, and does not interrupt or suspend the processing of subsequent PDUs; the encoding of subsequent PDUs continues using the incumbent codebook while the candidate codebook is evaluated during the staged deployment period of steps 505 through 509.

Following both the No branch of decision step 819 and the completion of the staged rollout initiation at step 820, the method arrives at step 821, which represents the completion of the processing cycle for the current PDU and the preparation to receive the next outgoing PDU from the CPU core. The outer loop of method 800 returns from step 821 to step 802 via the loop path shown, initiating the next PDU processing cycle. This continuous per-PDU loop implements the real-time adaptive compression behavior of the CPU-side compression engine 200, in which every outgoing PDU contributes to the occurrence statistics maintained in occurrence counter array 220, every PDU is encoded using the best available directional codebook for its traffic class and the current data distribution, and the codebook is continuously refined in response to the evolving statistical characteristics of the CPU-to-GPU traffic stream without any interruption to the encoding and decoding data path.

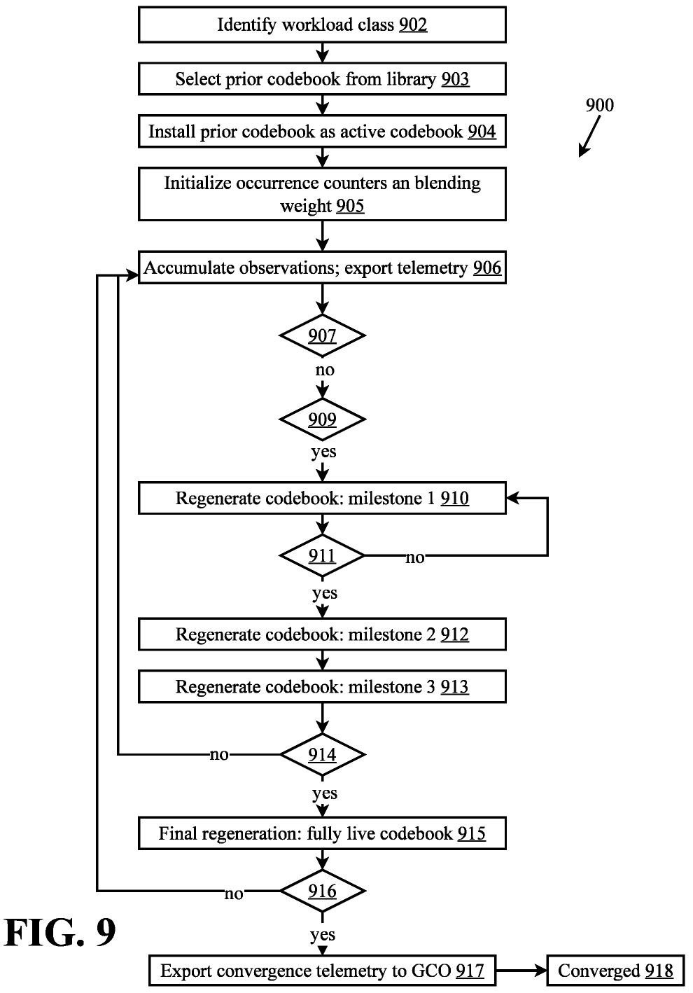

FIG. 9 is a process flow diagram illustrating an exemplary rapid ramp-up bootstrap process 900 executed by codebook lifecycle manager 225 upon entry into bootstrap state 320 of state machine 300. The process 900 expands bootstrap state 320 into its constituent sequential steps, providing the process-level written description support for the bootstrap and GCO-accelerated ramp-up operations described in connection with Claims 8 and 9. The rapid ramp-up bootstrap process 900 addresses the cold-start problem that arises whenever occurrence counter array 220 is empty and no live observation data has been accumulated, a condition that occurs at system initialization, following a switch to a new sourceblock length, following a major data distribution shift that triggers the transition from converged state 330 to bootstrap state 320 via transition 332, or following restoration of a checkpointed state from deep-sleep sub-state 384 in circumstances where the checkpointed statistics are no longer representative of the current traffic distribution. The central innovation of process 900 is the elimination of the cold-start penalty through the immediate installation of a pre-seeded prior codebook at step 904, enabling compression to begin on the first input PDU without any observation window delay, combined with the progressive blended refinement of steps 910 through 915 that transitions the active codebook from the prior to a fully live-trained codebook along a smooth trajectory that avoids the abrupt performance discontinuity that would result from a hard switch at the end of the observation window. The process 900 concludes at converged state 918, which corresponds to converged state 330, upon confirmation that the live-trained codebook has stabilized. The specific milestone fractions, blending weights, and convergence threshold values referenced herein are configurable parameters whose default values are illustrative and non-limiting.

The process 900 is entered at start step 901, which represents the firing of a bootstrap trigger. The bootstrap trigger that initiates process 900 may be fired by any of the following conditions: system initialization, in which the computing system 100 is powering on or resuming from a state in which no codebook is active; a source block length switch, in which source block length selector 222 has selected a new optimal source block length and the occurrence counter array for the new length has been reset to empty; a major data distribution shift, in which the compaction factor estimated by compaction factor estimator 221 has deteriorated beyond the shift threshold sustained over the shift detection period, triggering transition 332 from converged state 330 to bootstrap state 320; or a directive from codebook lifecycle manager 225 in response to a workload transition signal received from the Global Compression Orchestrator via GCO interface 228 that indicates the current prior codebook is no longer appropriate for the anticipated workload.

At step 902, the computing system identifies the workload class of the CPU-to-GPU traffic stream to be served by the directional codebook that will be produced by process 900. The workload class identification at step 902 may be performed using any one or more of the following mechanisms: a static configuration established at provisioning time that specifies the expected data class and sourceblock length for the CPU-to-GPU direction of the computing system; a workload class signal received from a compute job scheduler when a new workload is launched on the computing system, identifying the traffic class of the workload, for example, machine learning inference serving, distributed training, or graphics rendering, that will dominate the CPU-to-GPU traffic during the job's execution; a seed broadcast received from the Global Compression Orchestrator via GCO interface 228 that specifies the workload class and, in preferred embodiments, the identifier of a suitable prior codebook in prior codebook library 227; or a heuristic derived from the traffic source and destination identifiers observed in the most recent PDUs received at step 802, which may provide a reliable indicator of the workload class when no explicit workload class signal is available. In embodiments in which multiple workload class identification mechanisms are simultaneously available, codebook lifecycle manager 225 applies a configurable priority ordering among them, with explicit scheduler signals and GCO seed broadcasts taking precedence over heuristics derived from observed traffic patterns.

At step 903, the computing system selects the prior codebook from prior codebook library 227 whose characteristics most closely match the workload class identified at step 902. Prior codebook library 227 organizes its stored prior codebooks along three dimensions: the data class of the traffic, for example, machine learning activation tensors, kernel launch descriptors, model weight tensors, network packet payloads, or storage I/O data, the source block length n* for which each prior codebook was trained, corresponding to the candidate length at which the corresponding data class is known to achieve optimal or near-optimal compression performance; and the architectural and geographic context of the compression domain, for example, the prior for CPU-to-GPU traffic in a machine learning training cluster may differ from the prior for CPU-to-GPU traffic in a graphics rendering workstation even when both are nominally carrying the same data class, reflecting differences in the specific byte-level distributions arising from different hardware configurations, software stacks, and workload parameterizations. The selection at step 903 identifies the prior codebook in library 227 that minimizes the expected statistical distance between the prior's training distribution and the anticipated traffic distribution of the current workload class, providing the best available initialization for the blended ramp-up process that follows.

At step 904, the computing system installs the prior codebook selected at step 903 as the active directional codebook in primary codebook 224a of directional codebook store 224, using the shadow codebook pointer flip mechanism to ensure that installation is atomic and that the encoding data path is not interrupted. Following the installation at step 904, encoder 117 immediately begins encoding outgoing PDUs using the installed prior codebook, and the corresponding prior codebook version is communicated to the GPU-side decoder via the PCSP handshake to ensure that the GPU-side decoder is prepared to decode frames encoded under the prior codebook version from the first frame. The installation at step 904eliminates the cold-start penalty of prior art systems, which disable compression entirely during the initial observation period or apply a generic pre-built codebook that is poorly matched to the actual traffic distribution: by immediately installing a prior codebook matched to the identified workload class, process 900 provides meaningful compression benefit from the first PDU while occurrence counter array 220 accumulates live statistics that will progressively improve the codebook over the course of the ramp-up period.

At step 905, the computing system initializes occurrence counter array 220 to empty, with all occurrence counts set to zero and the total observation count set to zero, and initializes the blending weight to zero, corresponding to full prior weight and zero live weight at the start of the ramp-up period. The initialization of step 905 establishes the starting conditions for the observation accumulation loop of step 906 and the blending weight progression of steps 910 through 915. In embodiments in which a GCO donor occurrence summary is subsequently incorporated at step 908, the effective starting blending weight may be increased above zero by the incorporation of the donor statistics, as described further below.

At step 906, the computing system operates in the continuous observation accumulation mode of bootstrap state 320, encoding outgoing PDUs using the currently active codebook, which at the start of the ramp-up period is the prior codebook installed at step 904 and which is progressively replaced by blended codebooks at steps 910 through 915 as the ramp-up milestones are reached, while simultaneously updating occurrence counter array 220 with the symbol pattern statistics of each processed PDU as described in connection with step 803. Concurrently with the observation accumulation, step 906 exports ramp-up status telemetry to performance monitor 215 and GCO interface 228 at the configured reporting interval. The telemetry exported at step 906 includes the current observation count w, the ramp-up completion fraction w/W representing the proportion of the target observation window that has been filled with live observations, the current blended compaction factor K derived from the blended probability estimates of the current blended codebook, and the estimated time to full window computed from the current observation rate. This telemetry enables the Global Compression Orchestrator to monitor the ramp-up progress of the bootstrapping domain and to prioritize ramp-up assistance resources, including the provision of donor occurrence counter summaries at step 908, toward domains with the slowest ramp-up progress or the largest expected compression benefit upon convergence.

Following each observation accumulation cycle at step 906, decision step 907 evaluates whether the Global Compression Orchestrator has provided a donor occurrence counter summary to the bootstrapping domain via GCO interface 228. A donor occurrence counter summary is a compact representation of the symbol pattern frequency distribution of a donor compression domain identified by the Global Compression Orchestrator as having traffic characteristics similar to those of the bootstrapping domain's identified workload class. When a donor occurrence summary has been received, corresponding to the Yes branch of decision step 907, the method proceeds to step 908, at which the computing system incorporates the donor occurrence summary into the blended probability estimates used by codebook generator 223 as a high-weight prior component, supplementing or replacing the prior codebook probability estimates from prior codebook library 227 with the donor domain's observed occurrence statistics. The incorporation of the donor occurrence summary at step 908 is equivalent to seeding the blended ramp-up with a large number of high-quality prior observations derived from a domain with similar traffic characteristics, and in preferred embodiments can reduce the effective cold-start window from the full target observation window W to as few as one-tenth of W, materially reducing the duration of degraded compression performance during workload transitions. Following step 908, the method rejoins the main flow at decision step 909. When no donor occurrence summary has been received, corresponding to the No branch of decision step 907 the method proceeds directly to decision step 909 without modification of the blended probability estimates.

Decision step 909 evaluates whether the first blended regeneration milestone has been reached, specifically whether the accumulated observation count w has reached one-quarter of the target observation window size W. When the first milestone has not yet been reached, corresponding to the No branch of decision step 909, the method returns to step 906 to continue accumulating observations and exporting telemetry. When the first milestone has been reached, corresponding to the Yes branch of decision step 909, the method proceeds to step 910.

At step 910, the computing system performs the first blended codebook regeneration of the ramp-up process. Codebook generator 223 generates an updated codebook using blended probability estimates in which the live empirical probability derived from occurrence counter array 220 is weighted at one-quarter of the total blending weight and the prior probability from prior codebook library 227, or the donor occurrence summary incorporated at step 908 if one has been received, is weighted at three-quarters of the total blending weight. The blended codebook generated at step 910 therefore reflects primarily the prior distribution while incorporating the first quarter-window of live observations, producing a codebook that is better matched to the actual traffic distribution than the pure prior installed at step 904 while still relying substantially on the prior for statistical reliability. The codebook generated at step 910 is installed as the active codebook via the shadow codebook pointer flip mechanism of primary codebook 224a, ensuring that the installation is atomic and that the encoding data path is not interrupted during the codebook transition.

Decision step 911 evaluates whether the second blended regeneration milestone has been reached, specifically whether the accumulated observation count w has reached one-half of the target observation window size W. When the second milestone has not yet been reached, corresponding to the No branch of decision step 911, the method returns to the accumulation loop to continue accumulating observations, exporting telemetry, and checking for GCO donor summary receipt, until the second milestone is reached. When the second milestone has been reached, corresponding to the Yes branch of decision step 911, the method proceeds to step 912.

At step 912, the computing system performs the second blended codebook regeneration. Codebook generator 223 generates an updated codebook using blended probability estimates in which the live empirical probability and the prior probability are weighted equally at one-half of the total blending weight each, reflecting the equal contribution of the half-window of live observations and the prior at this intermediate stage of the ramp-up process. The codebook generated at step 912 is installed via the shadow codebook pointer flip, and the method continues accumulating observations.

At step 913, the computing system performs the third blended codebook regeneration upon reaching the third milestone at three-quarters of the target observation window size. Codebook generator 223 generates an updated codebook using blended probability estimates in which the live empirical probability is weighted at three-quarters of the total blending weight and the prior probability is weighted at one-quarter, reflecting the dominant contribution of the three-quarter window of live observations at this advanced stage of the ramp-up. The codebook generated at step 913 is installed via the shadow codebook pointer flip, and the method continues accumulating observations toward the full observation window.

Decision step 914 evaluates whether the full observation window has been filled, specifically whether the accumulated observation count w has reached the target window size W. When the full window has not yet been filled, corresponding to the No branch of decision step 914, the method returns to the accumulation loop to continue accumulating observations and exporting telemetry until the full window is reached. When the full window has been filled, corresponding to the Yes branch of decision step 914, the method proceeds to step 915.

At step 915, the computing system performs the final blended codebook regeneration of the ramp-up process. Codebook generator 223 generates the fully live-trained codebook using probability estimates derived entirely from the live occurrence statistics accumulated in occurrence counter array 220, with a blending weight of one, corresponding to full live weight and zero prior weight, such that the prior codebook's probability estimates no longer contribute to the generated codebook. Following the generation at step 915, the prior codebook is retired from prior codebook library 227's active selection for this domain, and all subsequent codebook generation cycles, whether triggered by the generation trigger conditions of step 819 or by the staged rollout and rollback process, will use exclusively live occurrence statistics from occurrence counter array 220 without any prior blending component. The fully live-trained codebook generated at step 915 is installed via the shadow codebook pointer flip, completing the progressive transition from the prior codebook installed at step 904 to the fully data-driven codebook that characterizes the converged operating state.

Decision step 916 evaluates whether the compaction factor estimated by compaction factor estimator 221 has stabilized following the installation of the fully live-trained codebook at step 915. Stability is assessed by evaluating whether the rate of change of the compaction factor estimate over a configurable number of recent observation intervals falls below a configurable convergence threshold, indicating that the traffic distribution is sufficiently stationary that the live-trained codebook is reliably representative of the current distribution and that further accumulation of observations is unlikely to produce material improvement in the codebook. When the stability condition is not satisfied, corresponding to the No branch of decision step 916, which may arise when the traffic distribution is still evolving following a workload transition or when the observation window is too short relative to the timescale of distribution changes, the method returns to the accumulation loop to continue accumulating observations on live data, periodically evaluating the stability condition until it is satisfied. In embodiments implementing GCO-accelerated ramp-up at step 908, the effective cold-start window may be sufficiently short that stability is achieved substantially before the full observation window W is reached, enabling an early transition to converged state 918 without waiting for all four regeneration milestones of steps 910 through 915 to be traversed sequentially.

At step 917, upon satisfaction of the convergence condition at decision step 916, the computing system exports final convergence telemetry to the Global Compression Orchestrator via GCO interface 228. The convergence telemetry exported at step 917 includes the final compaction factor K achieved by the fully live-trained codebook, the version number of the codebook installed at step 915, the total duration of the ramp-up process from the bootstrap trigger at step 901 to the convergence confirmation at step 916, and the observation count at which convergence was achieved. This telemetry enables the Global Compression Orchestrator to update its fabric-level compression performance map, to assess the effectiveness of any donor occurrence summary provided at step 908 in accelerating the ramp-up process, and to calibrate its future ramp-up assistance decisions for domains with similar traffic characteristics. In preferred embodiments, the convergence telemetry exported at step 917 additionally includes a compact occurrence counter summary of the converged domain's probability distribution, enabling the Global Compression Orchestrator to store this domain as a candidate donor for future ramp-up assistance to other domains with similar traffic characteristics, creating a self-reinforcing fabric-level ramp-up acceleration mechanism over time.

The process 900 concludes at converged state 918, representing the entry of codebook lifecycle manager 225 into converged state 330 with the fully live-trained codebook active, compression performance telemetry being exported at the configured reporting interval, and the lifecycle manager prepared to evaluate the generation trigger conditions that would initiate the staged rollout and rollback process in response to ongoing evolution of the CPU-to-GPU traffic distribution. The process 900 is representative of one embodiment, and one skilled in the art will appreciate that the number and timing of the blended regeneration milestones, the specific blending weights applied at each milestone, the convergence threshold applied at decision step 916, and the specific telemetry items exported at steps 906 and 917 are all configurable parameters that may be varied to optimize the ramp-up performance for specific deployment environments and workload characteristics without departing from the scope of the present disclosure.

### Exemplary Computing Environment

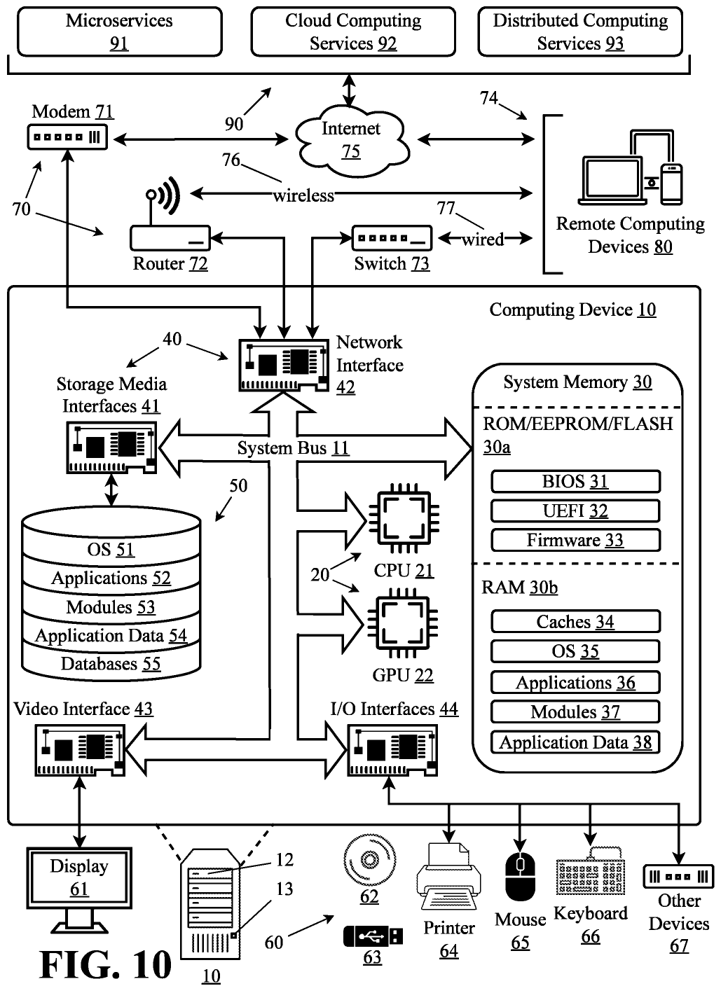

FIG. 10 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 13 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed and includes memory types such as read only memory (ROM), electronically erasable programmable memory (EEPROM), and rewritable solid-state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM) and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors but is more expensive and consumes more power compared to dynamic random access memory (DRAM). SRAM retains data as long as power is supplied. DRAM is the main memory in most computer systems and is slower than SRAM but cheaper and denser. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92 but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like Docker and container orchestration systems like Kubernetes, is a common approach for deploying and managing applications. Containers are created from images, which are lightweight, standalone, and executable packages that include application code, libraries, dependencies, and runtime. Images are often built from a Dockerfile or similar, which contains instructions for assembling the image. Dockerfiles are configuration files that specify how to build a Docker image. Systems like Kubernetes also support containerd or CRI-O. They include commands for installing dependencies, copying files, setting environment variables, and defining runtime configurations. Docker images are stored in repositories, which can be public or private. Docker Hub is an exemplary public registry, and organizations often set up private registries for security and version control using tools such as Hub, JFrog Artifactory and Bintray, Gitlab, Github Packages or Container registries. Containers can communicate with each other and the external world through networking. Docker provides a bridge network by default, but can be used with custom networks. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerd resources is used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A computing system comprising at least one processor, a memory, and a plurality of programming instructions stored in a non-transitory medium that, when operating on the at least one processor, cause the computing system to:
maintain a first occurrence counter array in memory that accumulates, for each distinct multi-byte symbol pattern observed in data transmitted from a central processing unit (CPU) to a graphical processing unit (GPU) across a PCIe, NVLink, or equivalent interface, a count of the number of times that symbol pattern has been observed in that direction;
maintain a second occurrence counter array in memory that accumulates, for each distinct multi-byte symbol pattern observed in data transmitted from the GPU to the CPU across the same interface, a count of the number of times that symbol pattern has been observed in that direction;
generate a first directional codebook by applying a codebook generation algorithm to the first occurrence counter array;
generate a second directional codebook by applying the codebook generation algorithm independently to the second occurrence counter array, wherein the second directional codebook is generated and updated independently of the first directional codebook and shares no training state with the first directional codebook;
encode each protocol data unit (PDU) transmitted from the CPU to the GPU by substituting, for each multi-byte symbol pattern in the PDU, the codeword assigned to that symbol pattern by the first directional codebook;
encode each PDU transmitted from the GPU to the CPU by substituting, for each multi-byte symbol pattern in the PDU, the codeword assigned to that symbol pattern by the second directional codebook; and
embed a codebook version number in the header of each encoded PDU identifying which version of the applicable directional codebook was used to encode that PDU.

2. The computing system of claim 1, wherein the programming instructions further cause the computing system to enforce a no-symmetry constraint such that the first directional codebook and the second directional codebook are at all times independently trained instances generated from independently accumulated occurrence statistics, and no codebook trained on one direction is used to encode or decode traffic in the other direction.

3. The computing system of claim 1, wherein the programming instructions further cause the computing system to:
classify each outgoing CPU-to-GPU PDU into one of a plurality of traffic classes comprising at least a kernel launch descriptor class and a model weight tensor class, based on one or more header fields of the PDU;
maintain a separate directional codebook for each traffic class in a codebook affinity table; and
select, for encoding each outgoing PDU, the directional codebook associated with the traffic class assigned to that PDU.

4. The computing system of claim 3, wherein the programming instructions further cause the computing system to:
assign each newly observed traffic flow that has not yet accumulated sufficient statistics to support a dedicated codebook to a general-purpose bootstrap codebook; and
promote a flow to dedicated codebook status, and trigger generation of a dedicated directional codebook for that flow, when the flow's cumulative transmitted data volume exceeds a configurable threshold.

5. The computing system of claim 1, wherein the programming instructions further cause the computing system to coordinate each codebook version transition through a four-phase handshake comprising:
transmitting, from the endpoint generating a new directional codebook, an announcement message carrying the new codebook version number, a scope identifier, a sourceblock length, and a cryptographic integrity tag;
upon receipt of the announcement message at the peer endpoint, validating the cryptographic integrity tag, installing the new codebook in a shadow codebook table without activating it, and transmitting a readiness acknowledgment;
upon receipt of the readiness acknowledgment, atomically activating the new codebook for all subsequent PDUs beginning at the next PDU boundary, with the first PDU encoded under the new codebook carrying the new version number in its header; and
after a configurable retirement window, retiring the previous codebook version such that PDUs arriving after the retirement window carrying the old version number are treated as version-mismatch errors.

6. The computing system of claim 1, wherein the programming instructions further cause the computing system to:
maintain, for each of a plurality of candidate sourceblock lengths, a corresponding occurrence counter array and an accumulator storing a running aggregate of the squared occurrence counts across all observed symbol patterns of that length;
compute, for each candidate sourceblock length, a scalar compression performance estimate derived from the squared-occurrence accumulator and the total observation count, without generating any codebook for any candidate length; and
select an optimal sourceblock length as the candidate length whose compression performance estimate indicates the greatest net compression benefit, and activate bypass mode if no candidate length yields a net compression benefit.

7. The computing system of claim 6, wherein the programming instructions further cause the computing system to:
trigger a switch from a currently active sourceblock length to a candidate sourceblock length only when the compression performance improvement offered by the candidate exceeds a configurable switching threshold;
apply a higher switching threshold when the candidate sourceblock length is longer than the currently active length than when it is shorter, thereby applying greater inertia against switches that would require a larger codebook and a longer ramp-up period; and
enforce a minimum dwell period at each sourceblock length, equal to the time required to accumulate a full observation window at that length, before permitting any subsequent switch.

8. The computing system of claim 1, wherein the programming instructions further cause the computing system to:
upon initialization of a directional codebook, immediately install a pre-seeded prior codebook selected from a stored library of prior codebooks organized by data class and sourceblock length, enabling compression of the first input PDU without waiting for an observation window to fill; and
as observations accumulate, generate updated codebooks using a blended probability estimate for each symbol pattern that combines an empirically observed probability derived from accumulated observations with a prior probability from the pre-seeded prior codebook, wherein the weight assigned to the empirically observed probability increases and the weight assigned to the prior probability decreases as the number of accumulated observations increases toward a target observation window size, and wherein the blending transitions fully to the empirically observed probability once the target observation window size is reached.

9. The computing system of claim 8, wherein the programming instructions further cause the computing system to:
receive, from a Global Compression Orchestrator, an occurrence counter summary from a donor compression domain identified by the Global Compression Orchestrator as having similar traffic characteristics to the directional codebook undergoing initialization; and
incorporate the received occurrence counter summary as a high-weight prior component in the blended probability estimate, thereby materially reducing the number of observations required to achieve a fully converged codebook compared to initialization without the donor summary.

10. The computing system of claim 1, wherein the programming instructions further cause the computing system to:
upon generation of a candidate directional codebook, apply a staged deployment process by initially encoding a configurable fraction of outgoing PDUs under the candidate codebook while encoding remaining PDUs under the incumbent codebook, each PDU carrying the version number of the codebook used to encode it;
fully deploy the candidate codebook only upon confirming, over a configurable confirmation period, that the candidate codebook provides a materially greater compression benefit than the incumbent codebook and that the candidate codebook's mismatch rate is within acceptable bounds; and
automatically reinstall the most recently superseded codebook version when, following full deployment, the observed compression performance deteriorates below the level achieved by the incumbent codebook at the time of deployment by more than a configurable amount sustained over a configurable period, the reinstallation performed by atomic pointer flip without interrupting in-flight PDUs.

11. The computing system of claim 1, wherein the programming instructions further cause the computing system to adapt directional codebook parameters in response to a current power state of the host processor, comprising:
in a full-performance state, maintaining a maximum codebook entry count and operating at a full codebook retraining frequency;
in a low-power state, reducing the active codebook entry count and reducing codebook retraining frequency to conserve power;
in a sleep-adjacent state, freezing the observation window to prevent accumulation of new occurrence statistics while preserving the current codebook in memory for immediate use upon wake without requiring a ramp-up period; and
in a deep-sleep state, checkpointing the current codebook and occurrence counter array to non-volatile storage before removing power from volatile memory, and restoring the checkpointed state upon wake within a bounded restoration time.

12. The computing system of claim 1, wherein the programming instructions further cause the computing system to:
attach to each generated directional codebook a cryptographic integrity tag computed over the codebook content and associated metadata including at least the version number, sourceblock length, and issuer identifier; and
prior to installing any received directional codebook, validate the cryptographic integrity tag and confirm that the version number of the received codebook is strictly greater than the highest version number previously installed from the same issuer, and reject without installation any codebook that fails either check.

13. The computing system of claim 1, wherein the programming instructions further cause the computing system to perform all compression performance estimation and codebook generation computations using only integer arithmetic and bit-shift operations, without any floating-point operation or lookup table, wherein each logarithmic computation is approximated using the position of the most significant bit of the integer operand.
